(19) United States
(12) Patent Application Publication
(10) Pub. No.: US 2024/0287310 A1
(43) Pub. Date: Aug. 29, 2024

(54) COLORING COMPOSITION, FILM, COLOR FILTER, DISPLAY DEVICE, AND STRUCTURAL BODY

(71) Applicant: FUJIFILM Corporation, Tokyo (JP)

(72) Inventor: Keiji YAMAMOTO, Haibara-gun (JP)

(73) Assignee: FUJIFILM Corporation, Tokyo (JP)

(21) Appl. No.: 18/644,587

(22) Filed: Apr. 24, 2024

Related U.S. Application Data
(63) Continuation of application No. PCT/JP2022/041102, filed on Nov. 4, 2022.

(30) Foreign Application Priority Data
Nov. 30, 2021 (JP) 2021-193785

(51) Int. Cl. C09B 47/04; C08J 5/18; C09B 29/52; C09B 57/04; C09D 4/06; C09D 7/41; C09D 7/63; G02B 5/22

(52) U.S. Cl. CPC C09B 47/04; C08J 5/18; C09B 29/3673; C09B 57/04; C09D 4/06; C09D 7/41; C09D 7/63; C08J 2300/00; G02B 5/223

(57) ABSTRACT

Provided are a coloring composition capable of forming a film having excellent light resistance, a film, a color filter, a display device, and a structure body. The coloring composition contains a colorant A, a resin, and a solvent, in which the colorant A contains a Color Index Pigment Green 7, a Color Index Pigment Yellow 185, and a colorant a including three or more colorants selected from colorants other than the Color Index Pigment Green 7 and the Color Index Pigment Yellow 185, and the coloring composition contains 200 to 3,000 parts by mass of the Color Index Pigment Green 7 with respect to 100 parts by mass of the Color Index Pigment Yellow 185.

### CROSS-REFERENCE TO RELATED APPLICATION

This application is a continuation application of International Application No., PCT/JP2022/041102 filed Nov. 4, 2022, the disclosure of which is incorporated herein by reference in its entirety. Further, this application claims priority from Japanese Patent Application No. 2021-193785, filed Nov. 30, 2021, the disclosure of which is incorporated herein by reference in their entirety.

### BACKGROUND OF THE INVENTION

### 1. Field of the Invention

The present invention relates to a coloring composition. More specifically, the present invention relates to a coloring composition used for forming a pixel of a color filter, or the like. In addition, the present invention relates to a film formed of the coloring composition, a color filter, a display device, and a structure body.

### 2. Description of the Related Art

In various display devices, a color filter is generally used to colorize display images. For example, JP2014-078037A discloses that a green color filter is manufactured using a coloring composition containing at least one green pigment selected from C. I. Pigment Green 7 and C. I. Pigment Green 36 and at least one yellow pigment selected from C. I. Pigment Yellow 139, C. I. Pigment Yellow 150, and C. I. Pigment Yellow 185.

### SUMMARY OF THE INVENTION

In recent years, there has been a demand for further improvement in light resistance of a film used for a color filter or the like.

According to studies of the present inventor, it has been found that there is room for further improvement in light resistance of the film to be obtained using the coloring composition disclosed in JP2014-078037A.

Therefore, an object of the present invention is to provide a coloring composition capable of forming a film having excellent light resistance. Another object of the present invention is to provide a film formed of the above-described coloring composition, a color filter, a display device, and a structure body.

According to the studies conducted by the present inventor, it has been found that the above-described object can be achieved by using a coloring composition which will be described later, thereby leading to completion of the present invention. The present invention provides the following.

<1> A coloring composition comprising:
a colorant A;
a resin; and
a solvent,
in which the colorant A contains
   a Color Index Pigment Green 7,
   a Color Index Pigment Yellow 185, and
   a colorant a including three or more colorants selected from colorants other than the Color Index Pigment Green 7 and the Color Index Pigment Yellow 185, and
the coloring composition contains 200 to 3,000 parts by mass of the Color Index Pigment Green 7 with respect to 100 parts by mass of the Color Index Pigment Yellow 185.

<2> The coloring composition according to <1>, in which a content of the Color Index Pigment Yellow 185 in the colorant A is 0.5 to 30 mass %.

<3> The coloring composition according to <1> or <2>, in which the colorant a includes one or more green colorants other than the Color Index Pigment Green 7 and two or more yellow colorants other than the Color Index Pigment Yellow 185.

<4> The coloring composition according to <3>, in which the yellow colorant includes at least two selected from the group consisting of a Color Index Pigment Yellow 129, a Color Index Pigment Yellow 139, a Color Index Pigment Yellow 150, and a Color Index Pigment Yellow 215.

<5> The coloring composition according to <3> or <4>, in which the green colorant includes at least one selected from the group consisting of a Color Index Pigment Green 36, a Color Index Pigment Green 58, and a Color Index Pigment Green 59.

<6> The coloring composition according to any one of <1> to <5>, in which the colorant a includes a Color Index Pigment Green 36, and the coloring composition contains 50 to 1,500 parts by mass of the Color Index Pigment Green 36 with respect to 100 parts by mass of the Color Index Pigment Yellow 185.

<7> The coloring composition according to any one of <1> to <6>, in which the colorant a includes a Color Index Pigment Yellow 139, and the coloring composition contains 260 to 3,000 parts by mass of the Color Index Pigment Yellow 139 with respect to 100 parts by mass of the Color Index Pigment Yellow 185.

<8> The coloring composition according to any one of <1> to <7>, in which the colorant a includes a Color Index Pigment Yellow 150, and the coloring composition contains 10 to 400 parts by mass of the Color Index Pigment Yellow 150 with respect to 100 parts by mass of the Color Index Pigment Yellow 185.

<9> The coloring composition according to any one of <1> to <8>, in which the colorant a includes a Color Index Pigment Yellow 139 and a Color Index Pigment Yellow 150, and the coloring composition contains 5 to 100 parts by mass of the Color Index Pigment Yellow 150 with respect to 100 parts by mass of the Color Index Pigment Yellow 139.

<10> The coloring composition according to any one of <1> to <9>, in which the colorant a includes a Color Index Pigment Yellow 139, a Color Index Pigment Yellow 150, and a Color Index Pigment Green 36.

<11> The coloring composition according to any one of <1> to <10>, in which a content of the colorant A in a total solid content of the coloring composition is 25 to 60 mass %.

<12> The coloring composition according to any one of <1> to <11>, further comprising:
a polymerizable monomer; and
a photopolymerization initiator.

<13> The coloring composition according to <12>, in which the polymerizable monomer includes a compound having an ethylenically unsaturated bond-containing group and an alkyleneoxy group.

<14> The coloring composition according to any one of <1> to <13>, further comprising:
a surfactant,
in which the surfactant includes a silicone-based surfactant.

<15> A film formed of the coloring composition according to any one of <1> to <14>.

<16> A color filter comprising:
the film according to <15>.

<17> A display device comprising:
the film according to <15>.

<18> A structure body comprising:
a green pixel formed of the coloring composition according to any one of <1> to <14>;
a red pixel; and
a blue pixel.

<19> The structure body according to <18>,
in which the red pixel contains a colorant including a Color Index Pigment Red 177, and
a content of the Color Index Pigment Red 177 in the colorant contained in the red pixel is 30 mass % or more.

According to the present invention, it is possible to provide a coloring composition capable of forming a film having excellent light resistance. In addition, according to the present invention, it is possible to provide a film formed of the above-described coloring composition, a color filter, a display device, and a structure body.

### DESCRIPTION OF THE PREFERRED EMBODIMENTS

Hereinafter, the details of the present invention will be described.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, generally, examples of the light used for exposure include an actinic ray or radiation, for example, a bright light spectrum of a mercury lamp, a far ultraviolet ray represented by excimer laser, an extreme ultraviolet ray (EUV light), an X-ray, or an electron beam.

In the present specification, a numerical range represented by “to” means a range including numerical values before and after “to” as a lower limit value and an upper limit value.

In the present specification, a total solid content denotes the total mass of all the components of the composition excluding a solvent.

In the present specification, a pigment means a colorant which is hardly dissolved in a solvent.

In the present specification, a dye means a colorant which is easily dissolved in a solvent.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, the term “step” is not only an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

### <Coloring Composition>

A coloring composition according to an embodiment of the present invention is a coloring composition containing a colorant A, a resin, and a solvent, in which the colorant A contains a Color Index Pigment Green 7, a Color Index Pigment Yellow 185, and a colorant a including three or more colorants selected from colorants other than the Color Index Pigment Green 7 and the Color Index Pigment Yellow 185, and the coloring composition contains 200 to 3,000 parts by mass of the Color Index Pigment Green 7 with respect to 100 parts by mass of the Color Index Pigment Yellow 185.

With the coloring composition according to the embodiment of the present invention, a film having excellent light resistance can be formed. The detailed reason for obtaining such an effect is not sure, but is presumed as follows.

The coloring composition according to the embodiment of the present invention contains Color Index Pigment Green 7, Color Index Pigment Yellow 185, and a colorant a including three or more colorants selected from colorants other than the Color Index Pigment Green 7 and the Color Index Pigment Yellow 185. That is, the coloring composition according to the embodiment of the present invention contains a total of five or more kinds of colorants. In addition, the coloring composition according to the embodiment of the present invention contains 200 to 3,000 parts by mass of the Color Index Pigment Green 7 with respect to 100 parts by mass of the Color Index Pigment Yellow 185. Since the coloring composition according to the embodiment of the present invention contains five or more kinds of colorants and the proportion of the Color Index Pigment Yellow 185 and the Color Index Pigment Green 7 is within the above-described range, it is presumed that a distance between the colorants is to be closer to each other in the film, and association of the colorants is likely to be formed. In addition, since the proportion of the Color Index Pigment Yellow 185 and the Color Index Pigment Green 7 is within the above-described range, it is presumed that, even in a case where the film is irradiated with light, the colorants in a photo-excited state can be rapidly deactivated and photodecomposition of the colorants can be suppressed. Therefore, it is presumed that a film having excellent light resistance can be formed by using the coloring composition according to the embodiment of the present invention.

In addition, a film formed of the coloring composition according to the embodiment of the present invention also has excellent moisture resistance. Since the coloring composition according to the embodiment of the present invention contains five or more kinds of colorants and the proportion of the Color Index Pigment Yellow 185 and the Color Index Pigment Green 7 is within the above-described range, it is presumed that hydrophilicity of the film is reduced by an interaction between these colorants or an interaction between these colorants and the resin, and thus intrusion of moisture into the film can be suppressed. Therefore, a film having excellent moisture resistance can be formed by using the coloring composition according to the embodiment of the present invention.

In the coloring composition according to the embodiment of the present invention, in a case where an absorbance of the coloring composition to light having a wavelength of 450 nm is set to 1, it is preferable that the coloring composition has a wavelength at which the absorbance is 0.2, in a wavelength range of 490 nm or more and 525 nm or less and a wavelength range of 550 nm or more and 600 nm or less, respectively.

From the viewpoint of color separation, the wavelength (hereinafter, also referred to as a wavelength λ1) on the short wavelength side, at which the above-described absorbance is 0.2, is preferably in a wavelength range of 490 nm or more and 520 nm or less, more preferably in a wavelength range of 495 nm or more and 520 nm or less, and still more preferably in a wavelength range of 500 nm or more and 515 nm or less. In addition, from the viewpoint of color separation, the wavelength (hereinafter, also referred to as a wavelength λ2) on the long wavelength side, at which the absorbance is 0.2, is preferably in a wavelength range of 555 nm or more and 600 nm or less, more preferably in a wavelength range of 555 nm or more and 595 nm or less, and still more preferably in a wavelength range of 560 nm or more and 585 nm or less.

From the viewpoint of color separation, a wavelength difference (λ2−λ1) between the wavelength λ2 and the wavelength λ1 is preferably 40 to 100 nm, more preferably 50 to 90 nm, and still more preferably 60 to 80 nm.

In the coloring composition according to the embodiment of the present invention, among absorbances to light having a wavelength of 400 to 700 nm, it is preferable to have a minimum value of the absorbances in a wavelength range of 505 nm or more and less than 565 nm, it is more preferable to have a minimum value of the absorbances in a wavelength range of 515 nm or more and 555 nm or less, and it is still more preferable to have a minimum value of the absorbances in a wavelength range of 525 nm or more and 545 nm or less. Hereinafter, among the absorbances to light having a wavelength of 400 to 700 nm, a wavelength exhibiting the minimum absorbance is also referred to as a wavelength λmin.

From the viewpoint of color separation, a wavelength difference (wavelength λmin−λ1) between the wavelength λmin and the wavelength λ1 is preferably 5 to 40 nm, more preferably 10 to 35 nm, and still more preferably 15 to 30 nm. In addition, from the viewpoint of color separation, a wavelength difference (wavelength λ2−wavelength λmin) between the wavelength 12 and the wavelength λmin is preferably 20 to 80 nm, more preferably 30 to 70 nm, and still more preferably 40 to 60 nm.

An absorbance Aλ at a wavelength λ is defined by the following equation (Ab1).

$$A λ = - log ( T λ / 100 ) \qquad ( Ab1 )$$

Aλ is an absorbance at the wavelength λ and TA is a transmittance (%) at the wavelength λ.

In the present invention, the value of the absorbance may be a value measured in the form of a solution, or may be a value measured in the form of a film formed using a coloring composition. In a case of measuring the absorbance in a state of the film, it is preferable to measure the absorbance of a film having a thickness of 2.0 μm, which is obtained by applying the coloring composition onto a glass substrate by a method such as spin coating, drying the coloring composition at 100° C. for 2 minutes using a hot plate or the like, exposing the coloring composition to light using an ultra-high pressure mercury lamp under conditions of a light illuminance of 20 mW/cm² and an exposure amount of 100 mJ/cm², heating the coloring composition on a hot plate at 100° C. for 20 minutes, and cooling the coloring composition to normal temperature. The absorbance can be measured using a known spectrophotometer of the related art.

In a case where a film having a film thickness of 0.6 to 3.0 μm is formed from the coloring composition according to the embodiment of the present invention, the maximum value of a transmittance to light having a wavelength of 505 nm or more and less than 565 nm in a thickness direction of the film is preferably 60% or more, more preferably 65% or more, and still more preferably 70% or more.

In addition, an average transmittance of the above-described film to light having a wavelength of 505 nm or more and less than 565 nm is preferably 55% or more, more preferably 60% or more, and still more preferably 65% or more.

In addition, a transmittance of the above-described film to light having a wavelength of 450 nm is preferably 10% or less, more preferably 5% or less, and still more preferably 2% or less.

In addition, an average transmittance of the above-described film to light having a wavelength of 400 nm or more and 450 nm or less is preferably 10% or less, more preferably 5% or less, and still more preferably 1% or less.

In addition, an average transmittance of the above-described film to light having a wavelength of 540 nm or more and 610 nm or less is preferably 60% or less, more preferably 50% or less, and still more preferably 40% or less.

In addition, the maximal absorption wavelength of the above-described film is preferably in a wavelength range of 410 to 445 nm, more preferably in a wavelength range of 415 to 440 nm, and still more preferably in a wavelength range of 420 to 435 nm.

In addition, the wavelength at which the transmittance of the above-described film is 50% is preferably in a wavelength range of 505 to 535 nm and in a wavelength range of 540 to 585 nm. The wavelength on the short wavelength side, at which the transmittance is 50%, is preferably in a wavelength range of 510 to 530 nm and more preferably in a wavelength range of 515 to 525 nm. The wavelength on the long wavelength side, at which the transmittance is 50%, is preferably in a wavelength range of 545 to 580 nm and more preferably in a wavelength range of 555 to 570 nm.

The coloring composition according to the embodiment of the present invention can be preferably used as a coloring composition for forming a pixel of a color filter, and can be more preferably used as a coloring composition for forming a green pixel of a color filter.

In a case where a film having a film thickness of 2.00 μm or less (preferably 1.98 μm or less) is formed of the coloring composition according to the embodiment of the present invention, it is preferable that chromaticity coordinates of the film in a case of being measured using a C light source in a CIE (International Commission on Illumination) XYZ color system are x=0.170 to 0.300 and y=0.600 to 0.800. The x of the chromaticity coordinates of the above-described film is preferably 0.210 to 0.300 and more preferably 0.250 to 0.300. The y of the chromaticity coordinates of the above-described film is preferably 0.650 to 0.800 and more preferably 0.700 to 0.800. A film having such chromaticity coordinates is preferably used as a green pixel of a color filter.

The coloring composition according to the embodiment of the present invention can be preferably used as a coloring composition for a display device. More specifically, the coloring composition according to the embodiment of the present invention can be preferably used as a coloring composition for forming a pixel of a color filter for a display device, and can be more preferably used as a coloring composition for forming a green pixel of a color filter for a display device. The type of display device is not particularly limited, and examples thereof include a display device having an organic semiconductor element such as an organic electroluminescent display device as a light source.

It is also preferable that the coloring composition according to the embodiment of the present invention is used for forming a film at a temperature of 150° C. or lower (preferably, a temperature of 120° C. or lower) throughout entire steps. In the present specification, forming a film at a temperature of 150° C. or lower throughout entire steps means that all steps of forming a film using the coloring composition are performed at a temperature of 150° C. or lower.

The thickness of the film and pixel formed by the coloring composition according to the embodiment of the present invention is preferably 0.5 to 3.0 μm. The lower limit thereof is preferably 0.8 μm or more, more preferably 1.0 μm or more, and still more preferably 1.1 μm or more. The upper limit thereof is preferably 2.5 μm or less, more preferably 2.0 μm or less, and still more preferably 1.8 μm or less.

In addition, the line width (pattern size) of the pixel formed by the coloring composition according to the embodiment of the present invention is preferably 2.0 to 10.0 μm. The upper limit thereof is preferably 7.5 μm or less, more preferably 5.0 μm or less, and still more preferably 4.0 μm or less. The lower limit thereof is preferably 2.25 μm or more, more preferably 2.5 μm or more, and still more preferably 2.75 μm or more.

Hereinafter, the coloring composition according to the embodiment of the present invention will be described in detail.

### <<Colorant A>>

The coloring composition according to the embodiment of the present invention contains a colorant A. The colorant A used in the coloring composition according to the embodiment of the present invention contains Color Index (C. I.) Pigment Green 7, C. I. Pigment Yellow 185, and a colorant a including three or more colorants selected from colorants other than the Color Index Pigment Green 7 and the Color Index Pigment Yellow 185.

Here, the C. I. Pigment Green 7 is a green colorant (green pigment), and the C. I. Pigment Yellow 185 is a yellow colorant (yellow pigment).

The coloring composition according to the embodiment of the present invention contains 200 to 3,000 parts by mass of the C. I. Pigment Green 7 with respect to 100 parts by mass of the C. I. Pigment Yellow 185. The upper limit thereof is preferably 2,500 parts by mass or less and more preferably 2,350 parts by mass or less. The lower limit thereof is preferably 300 parts by mass or more and more preferably 500 parts by mass or more.

The content of the C. I. Pigment Green 7 in the colorant A is preferably 10 to 50 mass %. The upper limit thereof is preferably 45 mass % or less and more preferably 40 mass % or less. The lower limit thereof is preferably 15 mass % or more and more preferably 20 mass % or more.

The content of the C. I. Pigment Yellow 185 in the colorant A is preferably 0.5 to 30 mass %. The upper limit thereof is preferably 20 mass % or less, more preferably 10 mass % or less, still more preferably 5 mass % or less, even more preferably 4 mass % or less, and still even more preferably 3.5 mass % or less. The lower limit thereof is preferably 1 mass % or more.

The total content of the C. I. Pigment Green 7 and the C. I. Pigment Yellow 185 in the colorant A is preferably 10 to 60 mass %. The upper limit thereof is preferably 55 mass % or less and more preferably 50 mass % or less. The lower limit thereof is preferably 15 mass % or more and more preferably 25 mass % or more.

An average primary particle diameter of the C. I. Pigment Green 7 is preferably 30 to 200 nm, more preferably 30 to 150 nm, and still more preferably 30 to 100 nm. In addition, an average primary particle diameter of the C. I. Pigment Yellow 185 is preferably 30 to 200 nm, more preferably 30 to 150 nm, and still more preferably 30 to 100 nm. In the present specification, a primary particle diameter of a pigment such as the C. I. Pigment Green 7 and the C. I. Pigment Yellow 185 can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present specification is the arithmetic average value of the primary particle diameters with respect to 400 primary particles of the pigment. In addition, the primary particle of the pigment refers to a particle which is independent without aggregation.

For the C. I. Pigment Green 7 and the C. I. Pigment Yellow 185, a crystal grain size obtained from a half-width of a peak derived from any crystal plane in the X-ray diffraction spectrum, in a case where CuKα ray is used as an X-ray source, is preferably 0.1 to 100 nm, more preferably 0.5 to 50 nm, still more preferably 1 to 30 nm, and particularly preferably 5 to 25 nm.

The above-described colorant a preferably includes at least one selected from a green colorant or a yellow colorant, and more preferably includes one or more green colorants other than the C. I. Pigment Green 7 (hereinafter, also referred to as a green colorant G1) and two or more yellow colorants other than the C. I. Pigment Yellow 185 (hereinafter, also referred to as a yellow colorant Y1). The green colorant G1 and the yellow colorant Y1 may be a dye, but are preferably a pigment.

An average primary particle diameter of the pigment is preferably 30 to 200 nm, more preferably 30 to 150 nm, and still more preferably 30 to 100 nm.

In addition, for the pigment, a crystal grain size obtained from a half-width of a peak derived from any crystal plane in the X-ray diffraction spectrum, in a case where CuKα ray is used as an X-ray source, is preferably 0.1 to 100 nm, more preferably 0.5 to 50 nm, still more preferably 1 to 30 nm, and particularly preferably 5 to 25 nm.

Examples of the green colorant G1 include a phthalocyanine compound and a squarylium compound, and a phthalocyanine compound is preferable. The green colorant G1 is preferably a green pigment. Specific examples of the green colorant G1 include green pigments such as C. I. Pigment Green 10, 36, 37, 58, 59, 62, 63, 64, 65, and 66. In addition, as the green colorant G1, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used. Specific examples thereof include the compounds described in WO2015/118720A. In addition, as the green colorant G1, compounds described in CN2010-6909027A, phthalocyanine compounds described in WO2012/102395A, which have phosphoric acid ester as a ligand, phthalocyanine compounds described in JP2019-008014A, phthalocyanine compounds described in JP2018-180023A, compounds described in JP2019-038958A, aluminum phthalocyanine compounds described in JP2020-070426A, core-shell type coloring agents described in JP2020-076995A, diarylmethane compounds described in JP2020-504758A, and the like can be used.

The green colorant G1 preferably includes at least one selected from the group consisting of C. I. Pigment Green 36, C. I. Pigment Green 58, and C. I. Pigment Green 59; and from the viewpoint of light resistance, it is more preferable to include C. I. Pigment Green 36 and it is still more preferable to be C. I. Pigment Green 36.

Examples of the yellow colorant Y1 include an azo compound, an azomethine compound, an isoindoline compound, a pteridine compound, a quinophthalone compound, and a perylene compound. Among these, at least one selected from an azomethine compound, an isoindoline compound, or a pteridine compound is preferable, and at least one selected from an azomethine compound or an isoindoline compound is more preferable. The yellow colorant Y1 is preferably a yellow pigment. Specific examples of the yellow colorant Y1 include yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 187, 188, 193, 194, 199, 213, 214, 215, 228, 231, 232, 233, 234, 235, and 236.

In addition, as the yellow colorant Y1, an azobarbituric acid-nickel complex having the following structure can also be used.

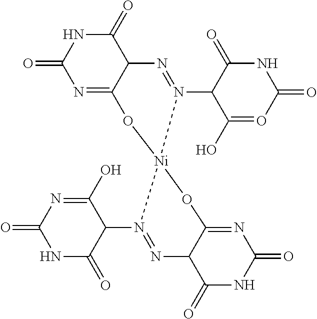

In addition, as the yellow colorant Y1, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765B (JP-S48-032765B), quinophthalone compounds described in JP2019-008014A, quinophthalone compounds described in JP6607427B, compounds described in KR10-2014-0034963A, compounds described in JP2017-095706A, compounds described in TW2019-20495A, compounds described in JP6607427B, compounds described in JP2020-033525A, compounds described in JP2020-033524A, compounds described in JP2020-033523A, compounds described in JP2020-033522A, compounds described in JP2020-033521A, compounds described in WO2020/045200A, compounds described in WO2020/045199A, compounds described in WO2020/045197A, azo compounds described in JP2020-093994A, perylene compounds described in WO2020/105346A, and quinophthalone compounds described in JP2020-517791A can also be used.

The yellow colorant Y1 preferably includes at least two selected from the group consisting of C. I. Pigment Yellow 129, C. I. Pigment Yellow 139, C. I. Pigment Yellow 150, and C. I. Pigment Yellow 215; and from the viewpoint of moisture resistance, it is more preferable to include C. I. Pigment Yellow 139 and C. I. Pigment Yellow 150, and it is still more preferable to be C. I. Pigment Yellow 139 and C. I. Pigment Yellow 150.

The above-described colorant a can further include a colorant other than the green colorant G1 and the yellow colorant Y1 (hereinafter, also referred to as other colorants). Examples of the other colorants include chromatic colorants such as a red colorant, a violet colorant, a blue colorant, and an orange colorant. The other colorants may be either a pigment or a dye.

Examples of the red colorant include a diketopyrrolopyrrole compound, an anthraquinone compound, an azo compound, a naphthol compound, an azomethine compound, a xanthene compound, a quinacridone compound, a perylene compound, and a thioindigo compound. Specific examples of the red colorant include red pigments such as Color Index (C. I.) Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297. In addition, as the red colorant, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, brominated diketopyrrolopyrrole compounds described in JP2020-085947A, naphtholazo compounds described in JP2012-229344A, red colorants described in JP6516119B, red colorants described in JP6525101B, brominated diketopyrrolopyrrole compounds described in paragraph No. 0229 of JP2020-090632A, anthraquinone compounds described in KR10-2019-0140741A, anthraquinone compounds described in KR10-2019-0140744A, perylene compounds described in JP2020-079396A, perylene compounds described in JP2020-083982A, xanthene compounds described in JP2018-035345A, diketopyrrolopyrrole compounds described in paragraph Nos. 0025 to 0041 of JP2020-066702A, and the like can also be used. In addition, as the red colorant, a compound having a structure that an aromatic ring group in which a group bonded with an oxygen atom, a sulfur atom, or a nitrogen atom is introduced to an aromatic ring is bonded to a diketopyrrolopyrrole skeleton can be used.

Examples of the orange colorant include orange pigments such as C. I. Pigment Orange 2, 5, 13, 16, 17:1, 31, 34, 36, 38, 43, 46, 48, 49, 51, 52, 55, 59, 60, 61, 62, 64, 71, and 73.

Examples of the violet colorant include violet pigments such as C. I. Pigment Violet 1, 19, 23, 27, 32, 37, 42, 60, and 61.

Examples of the blue colorant include C. I. Pigment Blue 1, 2, 15, 15:1, 15:2, 15:3, 15:4, 15:6, 16, 22, 29, 60, 64, 66, 79, 80, 87, and 88. In addition, as the blue colorant, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A. The blue colorant is preferably at least one selected from C. I. Pigment Blue 15:3, C. I. Pigment Blue 15:4, or C. I. Pigment Blue 16.

Examples of a preferred aspect of the above-described colorant a include an aspect in which the above-described colorant a is substantially only the green colorant G1 and the yellow colorant Y1. According to this aspect, the film to be obtained has more favorable brightness. In the present specification, the case where the colorant a is substantially only the green colorant G1 and the yellow colorant Y1 means that the total content of the green colorant G1 and the yellow colorant Y1 in the colorant a is 99 mass % or more, preferably 99.9 mass % or more and still more preferably 100 mass %.

Examples of another preferred aspect of the above-described colorant a include an aspect in which the above-described colorant a is only the green colorant G1, the yellow colorant Y1, and the blue colorant. According to this aspect, a color reproduction range of the film to be obtained is favorable. In the present specification, the case where the colorant a is substantially only the green colorant G1, the yellow colorant Y1, and the blue colorant means that the total content of the green colorant G1, the yellow colorant Y1, and the blue colorant in the colorant a is 99 mass % or more, preferably 99.9 mass % or more, and still more preferably 100 mass %. In addition, the blue colorant used in this aspect is preferably at least one selected from C. I. Pigment Blue 15:3, C. I. Pigment Blue 15:4, or C. I. Pigment Blue 16. In addition, the content of the blue colorant in the colorant a is preferably 10 to 200 parts by mass with respect to 100 parts by mass of the green colorant G1. The upper limit thereof is preferably 125 parts by mass or less and more preferably 50 parts by mass or less. The lower limit thereof is preferably 20 parts by mass or more and more preferably 30 parts by mass or more.

The above-described colorant a preferably includes C. I. Pigment Green 36. In addition, in this case, the coloring composition preferably contains 50 to 1,500 parts by mass of C. I. Pigment Green 36 with respect to 100 parts by mass of the C. I. Pigment Yellow 185. The upper limit thereof is preferably 1,300 parts by mass or less and more preferably 1,100 parts by mass or less. The lower limit thereof is preferably 100 parts by mass or more, more preferably 200 parts by mass or more, and still more preferably 500 parts by mass or more.

The above-described colorant a preferably includes C. I. Pigment Yellow 139. In addition, in this case, the coloring composition preferably contains 150 to 3,000 parts by mass and more preferably contains 260 to 3,000 parts by mass of C. I. Pigment Yellow 139, with respect to 100 parts by mass of the C. I. Pigment Yellow 185. The upper limit thereof is preferably 2,500 parts by mass or less and more preferably 2,250 parts by mass or less. The lower limit thereof is preferably 300 parts by mass or more, more preferably 400 parts by mass or more, and still more preferably 500 parts by mass or more.

The above-described colorant a preferably includes C. I. Pigment Yellow 150. In addition, in this case, the coloring composition preferably contains 10 to 400 parts by mass and more preferably contains 10 to 295 parts by mass of C. I. Pigment Yellow 150, with respect to 100 parts by mass of the C. I. Pigment Yellow 185. The upper limit thereof is preferably 290 parts by mass or less and more preferably 285 parts by mass or less. The lower limit thereof is preferably 25 parts by mass or more, more preferably 50 parts by mass or more, and still more preferably 100 parts by mass or more.

The above-described colorant a preferably includes C. I. Pigment Yellow 139 and C. I. Pigment Yellow 150. In addition, in this case, the coloring composition preferably contains 5 to 100 parts by mass of C. I. Pigment Yellow 150 with respect to 100 parts by mass of C. I. Pigment Yellow 139. The upper limit thereof is preferably 75 parts by mass or less and more preferably 50 parts by mass or less. The lower limit thereof is preferably 10 parts by mass or more.

The above-described colorant a preferably includes C. I. Pigment Yellow 139, C. I. Pigment Yellow 150, and C. I. Pigment Green 36. The total content of C. I. Pigment Yellow 139, C. I. Pigment Yellow 150, and C. I. Pigment Green 36 in the colorant a is preferably 20 to 100 mass %, more preferably 35 to 100 mass %, and still more preferably 50 to 100 mass %.

A content of the colorant A in the total solid content of the coloring composition is preferably 25 to 60 mass %. The upper limit thereof is preferably 55 mass % or less and more preferably 50 mass % or less. The lower limit thereof is preferably 30 mass % or more and more preferably 35 mass % or more.

The total content of the C. I. Pigment Green 7 and the C. I. Pigment Yellow 185 in the total solid content of the coloring composition is preferably 5 to 40 mass %. The upper limit thereof is preferably 30 mass % or less and more preferably 20 mass % or less. The lower limit thereof is preferably 10 mass % or more and more preferably 15 mass % or more.

The total content of the C. I. Pigment Green 7 and the above-described green colorant G1 in the total solid content of the coloring composition is preferably 5 to 45 mass %. The upper limit thereof is preferably 35 mass % or less and more preferably 25 mass % or less. The lower limit thereof is preferably 10 mass % or more and more preferably 15 mass % or more.

The total content of the C. I. Pigment Green 7 and C. I. Pigment Green 36 in the total solid content of the coloring composition is preferably 5 to 45 mass %. The upper limit thereof is preferably 35 mass % or less and more preferably 25 mass % or less. The lower limit thereof is preferably 10 mass % or more and more preferably 15 mass % or more.

The total content of the C. I. Pigment Yellow 185 and the above-described yellow colorant Y1 in the total solid content of the coloring composition is preferably 5 to 30 mass %. The upper limit thereof is preferably 25 mass % or less and more preferably 20 mass % or less. The lower limit thereof is preferably 7.5 mass % or more and more preferably 10 mass % or more.

The total content of C. I. Pigment Yellow 185, C. I. Pigment Yellow 139, and C. I. Pigment Yellow 150 in the total solid content of the coloring composition is preferably 5 to 35 mass %. The upper limit thereof is preferably 30 mass % or less and more preferably 25 mass % or less. The lower limit thereof is preferably 7.5 mass % or more and more preferably 10 mass % or more.

The total content of the C. I. Pigment Green 7, the C. I. Pigment Yellow 185, the above-described green colorant G1, and the above-described yellow colorant Y1 in the total solid content of the coloring composition is preferably 25 to 60 mass %. The upper limit thereof is preferably 55 mass % or less and more preferably 50 mass % or less. The lower limit thereof is preferably 30 mass % or more and more preferably 35 mass % or more.

The total content of the C. I. Pigment Green 7, C. I. Pigment Green 36, C. I. Pigment Yellow 185, C. I. Pigment Yellow 139, and C. I. Pigment Yellow 150 in the total solid content of the coloring composition is preferably 25 to 60 mass %. The upper limit thereof is preferably 55 mass % or less and more preferably 50 mass % or less. The lower limit thereof is preferably 30 mass % or more and more preferably 35 mass % or more.

It is preferable that the coloring composition contains 10 to 500 parts by mass in total of the C. I. Pigment Yellow 185 and the above-described yellow colorant Y1, with respect to 100 parts by mass in total of the C. I. Pigment Green 7 and the above-described green colorant G1. The upper limit thereof is preferably 300 parts by mass or less and more preferably 150 parts by mass or less. The lower limit thereof is preferably 20 parts by mass or more and more preferably 40 parts by mass or more.

It is preferable that the coloring composition contains 10 to 500 parts by mass in total of the C. I. Pigment Yellow 185, C. I. Pigment Yellow 139, and C. I. Pigment Yellow 150, with respect to 100 parts by mass in total of the C. I. Pigment Green 7 and C. I. Pigment Green 36. The upper limit thereof is preferably 300 parts by mass or less and more preferably 150 parts by mass or less. The lower limit thereof is preferably 20 parts by mass or more and more preferably 40 parts by mass or more.

### <<Resin>>

The coloring composition according to the embodiment of the present invention contains a resin. The resin is blended in, for example, an application for dispersing the pigment in the coloring composition or an application as a binder. A resin which is mainly used for dispersing pigments in the coloring composition is also referred to as a dispersant. The resin as a dispersant can be used in a case of preparing a dispersion liquid. However, such applications of the resin are merely exemplary, and the resin can also be used for other purposes in addition to such applications.

A weight-average molecular weight (Mw) of the resin is preferably 2,000 to 2,000,000. The upper limit thereof is preferably 1,000,000 or less and more preferably 500,000 or less. The lower limit thereof is preferably 3,000 or more, more preferably 4,000 or more, and still more preferably 5,000 or more.

Examples of the resin include a (meth)acrylic resin, a (meth)acrylamide resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, a styrene resin, and a siloxane resin. In addition, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, resins described in JP2017-066240A, resins described in JP2020-122052A, resins described in JP2020-111656A, resins described in JP2020-139021A, alkali-soluble resins having an urea-functional group, described in JP2020-139021A, resins including a constitutional unit having a ring structure in the main chain and a constitutional unit having a biphenyl group in the side chain, described in JP2017-138503A, resins described in paragraphs 0199 to 0233 of JP2020-186373A, alkali-soluble resins described in JP2020-186325A, and resins represented by Formula 1, described in KR10-2020-0078339A, can be used. In addition, as the resin, a resin having a glass transition temperature of 390° C. or higher can also be used. Examples of a commercially available product of the resin having a glass transition temperature of 390° C. or higher include Polyimide varnish H520 manufactured by MITSUBISHI GAS CHEMICAL COMPANY, INC.

The resin used in the present invention may have an acid group. Examples of the acid group include a carboxyl group, a phosphoric acid group, a sulfo group, and a phenolic hydroxy group. Among these acid groups, one kind may be used alone, or two or more kinds may be used in combination. The resin having an acid group preferably includes a repeating unit having an acid group in the side chain. The resin having an acid group can also be used as an alkali-soluble resin or a dispersant.

An acid value of the resin having an acid group is preferably 30 to 500 mgKOH/g. The lower limit thereof is preferably 50 mgKOH/g or more and more preferably 70 mgKOH/g or more. The upper limit thereof is preferably 400 mgKOH/g or less, more preferably 250 mgKOH/g or less, still more preferably 220 mgKOH/g or less, and particularly preferably 200 mgKOH/g or less.

The resin having an acid group may have a repeating unit derived from a maleimide compound. Examples of the maleimide compound include N-alkylmaleimide and N-arylmaleimide. Examples of the repeating unit derived from a maleimide compound include a repeating unit represented by Formula (C-mi).

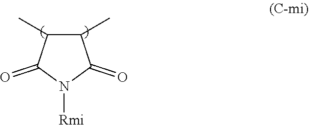

In Formula (C-mi), Rmi represents an alkyl group or an aryl group. The number of carbon atoms in the alkyl group is preferably 1 to 20. The alkyl group may be linear, branched, or cyclic. The number of carbon atoms in the aryl group is preferably 6 to 20, more preferably 6 to 15, and still more preferably 6 to 10. Rmi is preferably an aryl group.

As the resin having an acid group, a resin including a repeating unit derived from a compound represented by Formula (ED1) and/or a compound represented by Formula (ED2) (hereinafter, these compounds will also be referred to as an “ether dimer”) is also preferable.

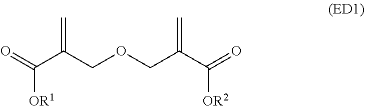

In Formula (ED1), R¹ and R² each independently represent a hydrogen atom or a hydrocarbon group having 1 to 25 carbon atoms, which may have a substituent.

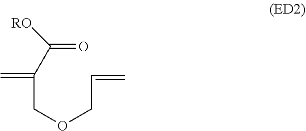

In Formula (ED2), R represents a hydrogen atom or an organic group having 1 to 30 carbon atoms. With regard to details of Formula (ED2), reference can be made to the description in JP2010-168539A, the contents of which are incorporated herein by reference. Specific examples of the ether dimer can be found in paragraph No. 0317 of JP2013-029760A, the contents of which are incorporated herein by reference.

Examples of the resin including a repeating unit derived from an ether dimer include resins having the following structures. In the following structural formulae, Me represents a methyl group.

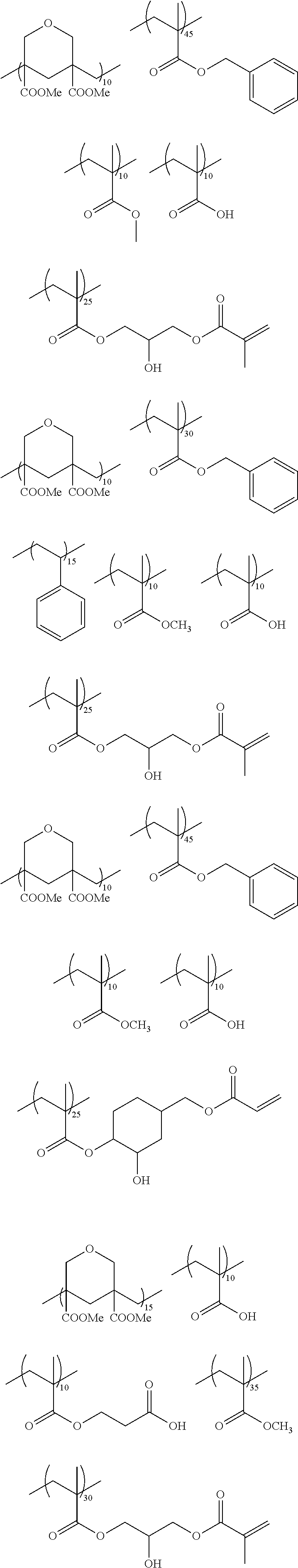

The coloring composition according to the embodiment of the present invention preferably contains a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit thereof is preferably 10 mgKOH/g or more and more preferably 20 mgKOH/g or more. The upper limit thereof is preferably 200 mgKOH/g or less and more preferably 100 mgKOH/g or less.

Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK-Chemie), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF). In addition, as the resin having a basic group, block copolymer (B) described in paragraph Nos. 0063 to 0112 of JP2014-219665A, block copolymer A1 described in paragraph Nos. 0046 to 0076 of JP2018-156021A, and a vinyl resin having a basic group, described in paragraph Nos. 0150 to 0153 of JP2019-184763A, can also be used, the contents of which are incorporated herein by reference.

It is also preferable that the coloring composition according to the embodiment of the present invention contains the resin having an acid group and the resin having a basic group, respectively. According to this aspect, the storage stability of the coloring composition can be further improved. In a case where the resin having an acid group and the resin having a basic group are used in combination, a content of the resin having a basic group is preferably 20 to 500 parts by mass, more preferably 30 to 300 parts by mass, and still more preferably 50 to 200 parts by mass with respect to 100 parts by mass of the resin having an acid group.

In the coloring composition according to the embodiment of the present invention, it is preferable to use a resin having a polymerizable group (hereinafter, also referred to as a polymerizable resin) as the resin. Examples of the polymerizable group include ethylenically unsaturated bond-containing groups such as a vinyl group, a (meth)allyl group, and a (meth)acryloyl group. By using the polymerizable resin, a film having excellent light resistance and moisture resistance can be formed. A polymerizable group value in the polymerizable resin is preferably 0.5 to 5.0 mmol/g. The upper limit thereof is preferably 4.0 mmol/g or less and more preferably 3.0 mmol/g or less. The lower limit thereof is preferably 1.0 mmol/g or more and more preferably 1.5 mmol/g or more. The polymerizable group value in the polymerizable resin is a numerical value representing a molar amount of polymerizable group per 1 g of the solid content of the polymerizable resin. In a case where the polymerizable group value in the polymerizable resin can be calculated from raw materials used for the synthesis of the polymerizable resin, a value calculated from the raw materials charged is used. In addition, in a case where the polymerizable group value in the polymerizable resin cannot be calculated from raw materials used for the synthesis of the polymerizable resin, for example, in a case of the ethylenically unsaturated bond-containing group, a value measured using a hydrolysis method is used. Specifically, a low-molecular-weight component (a) of polymerizable group site is extracted from the polymerizable resin by an alkali treatment, a content of the low-molecular-weight component is measured by high-performance liquid chromatography (HPLC), and the polymerizable group value in the polymerizable resin is calculated by the following expression. In a case where the polymerizable group cannot be extracted from the polymerizable resin by the alkali treatment, a value measured by a nuclear magnetic resonance (NMR) method is used.

$$Polymerizable Group Value [ mmol / g ] of Polymerizable Resin = ( Content [ ppm ] of Low ‐ Molecular ‐ Weight Component ( a ) / Molecular Weight [ g / mol ] of Low ‐ Molecular ‐ Weight Component ( a ) / ( Weighed Value [ g ] of Polymerizable Resin ) \times ( Concentration of Solid Contents [ mass \% ] of Polymerizable Resin / 100 ) \times 10 )$$

The resin used in the present invention also preferably contains a resin b1 which includes a repeating unit derived from a compound represented by Formula (III). By using the resin b1, a cured film having excellent curing properties at low temperatures and being sufficiently cured even by heating at a relatively low temperature can be formed. Furthermore, a cured film having excellent spectral characteristics is easily formed.

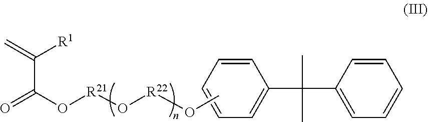

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (III) include ethylene oxide- or propylene oxide-modified (meth)acrylate of para-cumylphenol. Examples of a commercially available product thereof include ARONIX M-110 (manufactured by TOAGOSEI CO., LTD.).

A proportion of the repeating unit derived from the compound represented by Formula (III) in all repeating units of the resin b1 is preferably 1 to 99 mol %. The lower limit thereof is more preferably 3 mol % or more and still more preferably 5 mol % or more. The upper limit thereof is more preferably 95 mol % or less and still more preferably 90 mol % or less.

The resin b1 may further contain a repeating unit other than the repeating unit derived from the compound represented by Formula (III). For example, the resin b1 can contain a repeating unit derived from (meth)acrylate, and preferably contains a repeating unit derived from alkyl (meth)acrylate. The number of carbon atoms in an alkyl moiety of the alkyl (meth)acrylate is preferably 3 to 10, more preferably 3 to 8, and still more preferably 3 to 6. Preferred specific examples of the alkyl (meth)acrylate include n-butyl (meth)acrylate. In addition, it is also preferable that the resin b1 contains a repeating unit having an acid group.

It is also preferable that the resin used in the present invention contains a resin which has a repeating unit including a blocked isocyanate group (hereinafter, also referred to as a resin BI). According to this aspect, more excellent low temperature curing properties can be obtained, and a sufficiently cured film can be formed even by heating at a relatively low temperature.

The blocked isocyanate group included in the resin BI is preferably a group capable of generating an isocyanate group by heating, and more preferably a group capable of generating an isocyanate group by heating at 70° C. to 150° C. Examples of the blocked isocyanate group include a group having a structure in which an isocyanate group is chemically protected by a blocking agent. The blocked isocyanate group is a group having a structure in which an isocyanate group is protected by a compound called a blocking agent. Although the blocked isocyanate group does not exhibit reactivity as the isocyanate group at normal temperature (for example, 10° C. to 30° C.), the blocked isocyanate group is a group having a structure in which the blocking agent is eliminated from the blocked isocyanate group by heating or the like to generate the isocyanate group.

The blocked isocyanate group included in the resin BI is more preferably a group capable of generating an isocyanate group by heating at 70° C. to 150° C. That is, the isocyanate generation temperature of the blocked isocyanate group (elimination temperature of the blocking agent) is preferably 70° C. to 150° C. From the viewpoint of storage stability, the lower limit of the isocyanate generation temperature is preferably 75° C. or higher and more preferably 80° C. or higher. From the viewpoint of curing properties, the upper limit of the isocyanate generation temperature is preferably 130° C. or lower and more preferably 120° C. or lower.

Examples of the blocking agent which protects the isocyanate group of the blocked isocyanate group include an oxime compound, a lactam compound, a phenol compound, an alcohol compound, an amine compound, an active methylene compound, a pyrazole compound, a mercaptan compound, an imidazole compound, and an imide compound, and from the viewpoint of easiness of protecting reaction and deprotecting reaction, an oxime compound, a lactam compound, an active methylene compound, or a pyrazole compound is preferable, an oxime compound, an active methylene compound, or a pyrazole compound is more preferable, and an oxime compound is still more preferable.

The coloring composition according to the embodiment of the present invention can contain a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxy group. The acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

Examples of the dispersant include polymer dispersants [for example, polyamide amine or a salt thereof, polycarboxylic acid or a salt thereof, high molecular weight unsaturated acid ester, modified polyurethane, modified polyester, modified poly(meth)acrylate, a (meth)acrylic copolymer, and a naphthalene sulfonic acid formalin condensate], polyoxyethylene alkylphosphate ester, polyoxyethylene alkyl amine, and alkanolamine. The polymer dispersant can be further classified into a linear polymer, a terminal-modified polymer, a graft polymer, and a block polymer according to the structure thereof. The polymer dispersant acts to prevent reaggregation by absorbing on a surface of particles such as the pigment. Therefore, examples of a preferred structure of the polymer dispersant include a terminal-modified polymer, a graft polymer, and a block polymer, each of which has an anchor site for adsorbing on the surface of particles such as pigments. In addition, dispersants described in paragraph Nos. 0028 to 0124 of JP2011-070156A or dispersants described in JP2007-277514A are preferably used.

A graft copolymer can also be used as the dispersant. With regard to details of the graft copolymer, reference can be made to the description in paragraph Nos. 0131 to 0160 of JP2012-137564A, the contents of which are incorporated herein by reference. In addition, as the dispersant, an oligoimine copolymer including a nitrogen atom at at least one of a main chain or a side chain can also be used. With regard to the oligoimine-based copolymer, reference can be made to the description in paragraph Nos. 0102 to 0174 of JP2012-255128A, the contents of which are incorporated herein by reference. In addition, as the dispersant, a resin having a structure in which a plurality of polymer chains are bonded to a core portion can also be used. Examples of such a resin include dendrimers (including star polymers). In addition, specific examples of the dendrimer include polymer compounds C-1 to C-31 described in paragraph Nos. 0196 to 0209 of JP2013-043962A. In addition, as the dispersant, polyethyleneimine having a polyester side chain, described in WO2016/104803A, a block copolymer described in WO2019/125940A, a block polymer having an acrylamide structural unit, described in JP2020-066687A, a block polymer having an acrylamide structural unit, described in JP2020-066688A, or the like can also be used.

A commercially available product is also available as the dispersant, and specific examples thereof include DISPERBYK series (for example, DISPERBYK-111, 2001, and the like) and BYK series manufactured by BYK-Chemie Japan K.K., Solsperse series (for example, Solsperse 20000, 76500, and the like) manufactured by Lubrizol Corporation, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

A content of the resin in the total solid content of the coloring composition is preferably 5 to 50 mass %. The upper limit thereof is preferably 40 mass % or less and more preferably 30 mass % or less. The lower limit thereof is preferably 10 mass % or more and more preferably 20 mass % or more.

A content of the polymerizable resin in the total solid content of the coloring composition is preferably 1 to 40 mass %. The upper limit thereof is preferably 30 mass % or less and more preferably 20 mass % or less. The lower limit thereof is preferably 3 mass % or more and more preferably 5 mass % or more.

The content of the polymerizable resin in the resin contained in the coloring composition is preferably 10 to 100 mass %, more preferably 20 to 100 mass %, and still more preferably 30 to 100 mass %.

The coloring composition according to the embodiment of the present invention may contain one resin or two or more kinds of resins. In a case of containing two or more kinds of resins, the total amount thereof is preferably within the above-described range.

### <<Solvent>>

The coloring composition according to the embodiment of the present invention contains a solvent. Examples of the solvent include an organic solvent. Basically, the solvent is not particularly limited as long as it satisfies the solubility of the respective components and the application properties of the coloring composition. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph 0223 of WO2015/166779A, the contents of which are incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, 3-pentanone, 4-heptanone, cyclohexanone, 2-methylcyclohexanone, 3-methylcyclohexanone, 4-methylcyclohexanone, cycloheptanone, cyclooctanone, cyclohexyl acetate, cyclopentanone, ethylcarbitol acetate, butylcarbitol acetate, propylene glycol monomethyl ether, propylene glycol monomethyl ether acetate, 3-methoxy-N,N-dimethylpropanamide, 3-butoxy-N,N-dimethylpropanamide, propylene glycol diacetate, 3-methoxybutanol, methyl ethyl ketone, γ-butyrolactone, sulfolane, anisole, 1,4-diacetoxybutane, diethylene glycol monoethyl ether acetate, butane diacetate-1,3-diyl, dipropylene glycol methyl ether acetate, diacetone alcohol (also known as diacetone alcohol or 4-hydroxy-4-methyl-2-pentanone), 2-methoxypropyl acetate, 2-methoxy-1-propanol, and isopropyl alcohol. In this case, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 parts per billion (ppb) by mass or less. A solvent in which the metal content is at a level of parts per trillion (ppt) by mass may be used as desired, and such a high-purity solvent is provided by, for example, Toyo Kasei Kogyo Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore diameter of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms but having a different structure). In addition, only one kind of isomers may be included, or a plurality of isomers may be included.

A content of peroxides in the organic solvent is preferably 0.8 mmol/L or less, and it is more preferable that the organic solvent does not substantially contain the peroxides.

The content of the solvent in the coloring composition is preferably 60 to 95 mass %. The upper limit thereof is preferably 90 mass % or less, more preferably 87.5 mass % or less, and still more preferably 85 mass % or less. The lower limit thereof is preferably 65 mass % or more, more preferably 70 mass % or more, and still more preferably 75 mass % or more. The solvent may be used alone or in combination of two or more kinds thereof. In a case where two or more kinds thereof are used in combination, the total amount thereof is preferably within the above-described range.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition according to the embodiment of the present invention, and may be infiltrated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause cross-linking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or coloring composition produced by mixing these compounds.

### <<Polymerizable Monomer>>

It is preferable that the coloring composition according to the embodiment of the present invention contains a polymerizable monomer. Examples of the polymerizable monomer include a compound having an ethylenically unsaturated bond-containing group. Examples of the ethylenically unsaturated bond-containing group include a vinyl group, a (meth)allyl group, and a (meth)acryloyl group. The polymerizable monomer used in the present invention is preferably a radically polymerizable monomer.

A molecular weight of the polymerizable monomer is preferably 100 to 3,000. The upper limit thereof is preferably 2,000 or less and more preferably 1,500 or less. The lower limit thereof is preferably 150 or more and more preferably 250 or more.

From the viewpoint of temporal stability of the coloring composition, an ethylenically unsaturated bond-containing group value (hereinafter, referred to as a C═C value) of the polymerizable monomer is preferably 2 to 14 mmol/g. The lower limit thereof is preferably 3 mmol/g or more, more preferably 4 mmol/g or more, and still more preferably 5 mmol/g or more. The upper limit thereof is preferably 12 mmol/g or less, more preferably 10 mmol/g or less, and still more preferably 8 mmol/g or less. The C═C value of the polymerizable monomer is a value calculated by dividing the molecular weight of the polymerizable monomer by the number of ethylenically unsaturated bond-containing groups included in one molecule of the polymerizable monomer.

The polymerizable monomer is preferably a compound including three or more ethylenically unsaturated bond-containing groups, and more preferably a compound including four or more ethylenically unsaturated bond-containing groups. According to this aspect, curing properties of the coloring composition by exposure are favorable. From the viewpoint of temporal stability of the coloring composition, the upper limit of the number of ethylenically unsaturated bond-containing groups is preferably 15 or less, more preferably 10 or less, and still more preferably 6 or less. In addition, as the polymerizable monomer, a (meth)acrylate compound having 3 or more functional groups is preferable, a (meth)acrylate compound having 3 to 15 functional groups is more preferable, a (meth)acrylate compound having 3 to 10 functional groups is still more preferable, and a (meth)acrylate compound having 3 to 6 functional groups is particularly preferable.

It is also preferable that the polymerizable monomer is a compound including an ethylenically unsaturated bond-containing group and an alkyleneoxy group (hereinafter, also referred to as an AO monomer). By using the AO monomer, affinity with a developer such as an alkali developer can be improved. Therefore, in a case where a coloring composition layer formed of the coloring composition is exposed in a patterned manner and a non-exposed portion of the coloring composition layer is removed using a developer such as an alkali developer to form a pixel, the non-exposed portion of the coloring composition layer can be efficiently removed, and generation of a development residue can be more effectively suppressed.

The number of alkyleneoxy groups included in one molecule of the AO monomer is preferably 3 or more, and more preferably 4 or more. From the viewpoint of temporal stability of the coloring composition, the upper limit thereof is preferably 20 or less.

Examples of the AO monomer include a compound represented by Formula (AO-1).

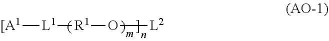

In the formula, A1 represents an ethylenically unsaturated bond-containing group, L¹ represents a single bond or a divalent linking group, R¹ represents an alkylene group, m represents an integer of 1 to 30, n represents an integer of 3 or more, and L² represents an n-valent linking group.

Examples of the ethylenically unsaturated bond-containing group represented by A¹ include a vinyl group, a (meth)allyl group, and a (meth)acryloyl group, and a (meth)acryloyl group is preferable.

Examples of the divalent linking group represented by L¹ include an alkylene group, an arylene group, —O—, —CO—, —COO—, —OCO—, —NH—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10.

The number of carbon atoms in the alkylene group represented by R¹ is preferably 1 to 10, more preferably 1 to 5, still more preferably 1 to 3, particularly preferably 2 or 3, and particularly preferably 2. The alkylene group represented by R¹ is preferably linear or branched, and more preferably linear. Specific examples of the alkylene group represented by R¹ include an ethylene group and a linear or branched propylene group, and an ethylene group is preferable.

m represents an integer of 1 to 30, and is preferably an integer of 1 to 20, more preferably an integer of 1 to 10, and still more preferably 1 to 5.

n represents an integer of 3 or more, and is preferably an integer of 4 or more. The upper limit of n is preferably an integer of 15 or less, more preferably an integer of 10 or less, and still more preferably an integer of 6 or less.

Examples of the n-valent linking group represented by L² include an aliphatic hydrocarbon group, an aromatic hydrocarbon group, a heterocyclic group, a group consisting of a combination thereof, and a group of a combination of at least one selected from an aliphatic hydrocarbon group, an aromatic hydrocarbon group, or a heterocyclic group, and at least one selected from —O—, —CO—, —COO—, —OCO—, or —NH—. The number of carbon atoms in the aliphatic hydrocarbon group is preferably 1 to 30, more preferably 1 to 20, and still more preferably 1 to 15. The aliphatic hydrocarbon group may linear, branched, or cyclic, and is preferably linear or branched. The number of carbon atoms in the aromatic hydrocarbon group is preferably 6 to 30, more preferably 6 to 20, and still more preferably 6 to 10. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be a single ring or a fused ring. The n-valent linking group represented by L² is also preferably a group derived from a polyfunctional alcohol.

As the AO monomer, a compound represented by Formula (AO-2) is more preferable.

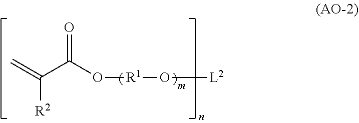

In the formula, R² represents a hydrogen atom or a methyl group, R¹ represents an alkylene group, m represents an integer of 1 to 30, n represents an integer of 3 or more, and L² represents an n-valent linking group. R¹, L², m, and n in Formula (AO-2) have the same meaning as R¹, L², m, and n in Formula (AO-1), and the preferred ranges thereof are also the same.

Examples of a commercially available product of the AO monomer include KAYARAD T-1420 (T) and RP-1040 (manufactured by Nippon Kayaku Co., Ltd.).

As the polymerizable monomer, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable monomer, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX M-402 (manufactured by TOAGOSEI CO., LTD.; mixture of dipentaerythritol hexaacrylate and dipentaerythritol pentaacrylate), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

As the polymerizable monomer, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable monomer, a polymerizable monomer having an acid group can also be used. By using a polymerizable monomer having an acid group, a coloring composition in a non-exposed portion is easily removed during development and the generation of the development residue can be suppressed. Examples of the acid group include a carboxy group, a sulfo group, and a phosphoric acid group, and a carboxy group is preferable. Examples of a commercially available product of the polymerizable monomer having an acid group include ARONIX M-305, M-510, M-520, and ARONIX TO-2349 (manufactured by TOAGOSEI CO., LTD.). An acid value of the polymerizable monomer having an acid group is preferably 0.1 to 40 mgKOH/g and more preferably 5 to 30 mgKOH/g. In a case where the acid value of the polymerizable monomer is 0.1 mgKOH/g or more, solubility in a developer is favorable, and in a case where the acid value of the polymerizable compound is 40 mgKOH/g or less, it is advantageous in production and handling.

As the polymerizable monomer, a polymerizable monomer having a caprolactone structure can also be used. Examples of the polymerizable monomer having a caprolactone structure include DPCA-20, DPCA-30, DPCA-60, and DPCA-120, each of which is commercially available as KAYARAD DPCA series from Nippon Kayaku Co., Ltd.

As the polymerizable monomer, a polymerizable monomer having a fluorene skeleton can also be used. Examples of a commercially available product of the polymerizable monomer having a fluorene skeleton include OGSOL EA-0200, EA-0300 (manufactured by Osaka Gas Chemicals Co., Ltd., (meth)acrylate monomer having a fluorene skeleton).

As the polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable monomer. In addition, the polymerizable monomers having an amino structure or a sulfide structure in the molecule, described in JP1988-277653A (JP-S63-277653A), JP1988-260909A (JP-S63-260909A), or JP1989-105238A (JP-H01-105238A), are also preferably used. In addition, as the polymerizable monomer, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

A content of the polymerizable monomer in the total solid content of the coloring composition is preferably 5 to 50 mass %. The upper limit thereof is preferably 45 mass % or less and more preferably 40 mass % or less. The lower limit thereof is preferably 10 mass % or more and more preferably 15 mass % or more.

A content of the above-described AO monomer in the total solid content of the coloring composition is preferably 5 to 50 mass %. The upper limit thereof is preferably 45 mass % or less and more preferably 40 mass % or less. The lower limit thereof is preferably 10 mass % or more and more preferably 15 mass % or more.

The content of the AO monomer in the polymerizable monomer contained in the coloring composition is preferably 30 to 100 mass %, more preferably 50 to 100 mass %, and still more preferably 70 to 100 mass %.

The coloring composition according to the embodiment of the present invention may contain one kind or two or more kinds of the polymerizable monomers. In a case of containing two or more kinds the polymerizable monomers, the total amount thereof is preferably within the above-described range.

### <<Photopolymerization Initiator>>

The coloring composition according to the embodiment of the present invention preferably contains a photopolymerization initiator. The photopolymerization initiator is not particularly limited, and can be appropriately selected from known photopolymerization initiators. For example, a compound having photosensitivity to rays in a range from an ultraviolet range to a visible range is preferable. The photopolymerization initiator is preferably a photoradical polymerization initiator.

Examples of the photopolymerization initiator include a halogenated hydrocarbon derivative (such as a compound having a triazine skeleton and a compound having an oxadiazole skeleton), an acylphosphine compound, a hexaaryl biimidazole compound, an oxime compound, an organic peroxide, a thio compound, a ketone compound, an aromatic onium salt, a hydroxyalkylphenone compound, an aminoalkylphenone compound, and a phenylglyoxylate compound. From the viewpoint of exposure sensitivity, the photopolymerization initiator is preferably at least one selected from an oxime compound, a hydroxyalkylphenone compound, an aminoalkylphenone compound, or an acylphosphine compound, and more preferably an oxime compound. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, peroxide initiators described in JP2019-167313A, aminoacetophenone-based initiators described in JP2020-055992A, oxime-based photopolymerization initiators described in JP2013-190459A, polymers described in JP2020-172619A, and the compound represented by Formula 1 described in WO2020/152120A, the contents of which are incorporated herein by reference.

Examples of the phenylglyoxylate compound include phenylglyoxylic acid methyl ester. Examples of a commercially available product thereof include Omnirad MBF (manufactured by IGM Resins B.V.) and Irgacure MBF (manufactured by BASF).

Examples of the acylphosphine compound include the acylphosphine compound described in JP4225898B. Specific examples thereof include bis(2,4,6-trimethylbenzoyl)-phenylphosphine oxide. Examples of a commercially available product of the acylphosphine compound include Omnirad 819 and Omnirad TPO (both of which are manufactured by IGM Resins B.V.), and Irgacure 819 and Irgacure TPO (both of which are manufactured by BASF).

Examples of the aminoalkylphenone compound include the aminoalkylphenone compound described in JP1998-291969A (JP-H10-291969A). In addition, examples of a commercially available product of the aminoalkylphenone compound include Omnirad 907, Omnirad 369, Omnirad 369E, Omnirad 379, and Omnirad 379EG (all of which are manufactured by IGM Resins B.V.), Irgacure 907, Irgacure 369, Irgacure 369E, Irgacure 379, and Irgacure 379EG (all of which are manufactured by BASF).

Examples of the hydroxyalkylphenone compound include a compound represented by Formula (V).

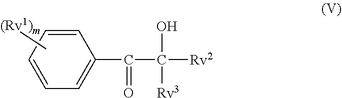

In the formula, Rv¹ represents a substituent, Rv² and Rv³ each independently represent a hydrogen atom or a substituent, Rv² and Rv³ may be bonded to each other to form a ring, and m represents an integer of 0 to 5.

Examples of the substituent represented by Rv¹ include an alkyl group (preferably an alkyl group having 1 to 10 carbon atoms) and an alkoxy group (preferably an alkoxy group having 1 to 10 carbon atoms). The alkyl group and alkoxy group are preferably linear or branched, and more preferably linear. The alkyl group and alkoxy group represented by Rv¹ may be unsubstituted or may have a substituent. Examples of the substituent include a hydroxy group and a group having a hydroxyalkylphenone structure. Examples of the group having a hydroxyalkylphenone structure include a group of a structure in which, in Formula (V), one hydrogen atom is removed from the benzene ring bonded with Rv¹ or from Rv¹.

Rv² and Rv³ each independently represent a hydrogen atom or a substituent. As the substituent, an alkyl group (preferably an alkyl group having 1 to 10 carbon atoms) is preferable. In addition, Rv² and Rv³ may be bonded to each other to form a ring (preferably a ring having 4 to 8 carbon atoms and more preferably an aliphatic ring having 4 to 8 carbon atoms). The alkyl group is preferably linear or branched, and more preferably linear.

Specific examples of the compound represented by Formula (V) include the following compounds.

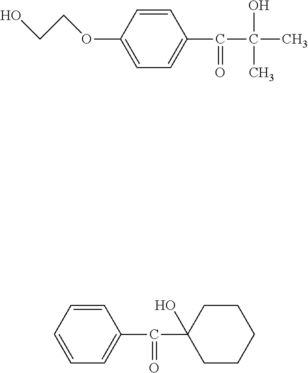 [SMILES: CC(C)(O)C(=O)c1ccc(OCCO)cc1 ; O=C(c1ccccc1)C1(O)CCCCC1]

Examples of a commercially available product of the hydroxyalkylphenone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A. Specific examples of the oxime compound include 3-benzoyloxyiminobutane-2-one, 3-acetoxyiminobutane-2-one, 3-2-acetoxyiminopentane-3-one, 2-acetoxyimino-1-propionyloxyiminobutane-2-one, phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product thereof include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, compounds described in JP6636081B, and compounds described in KR10-2016-0109444A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

Specific examples of the oxime compound which are preferably used in the present invention are shown below, but the present invention is not limited thereto.

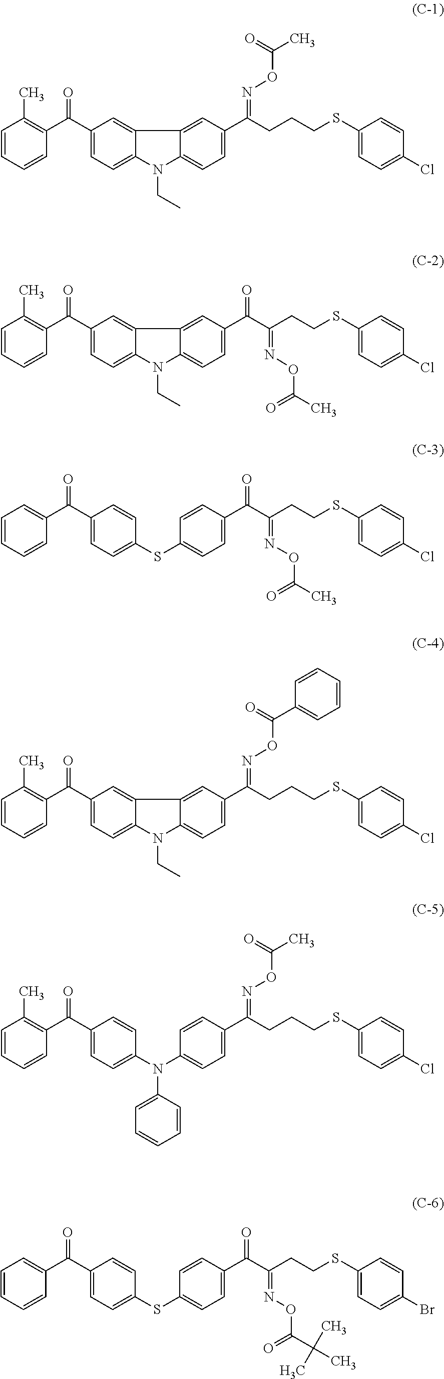 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

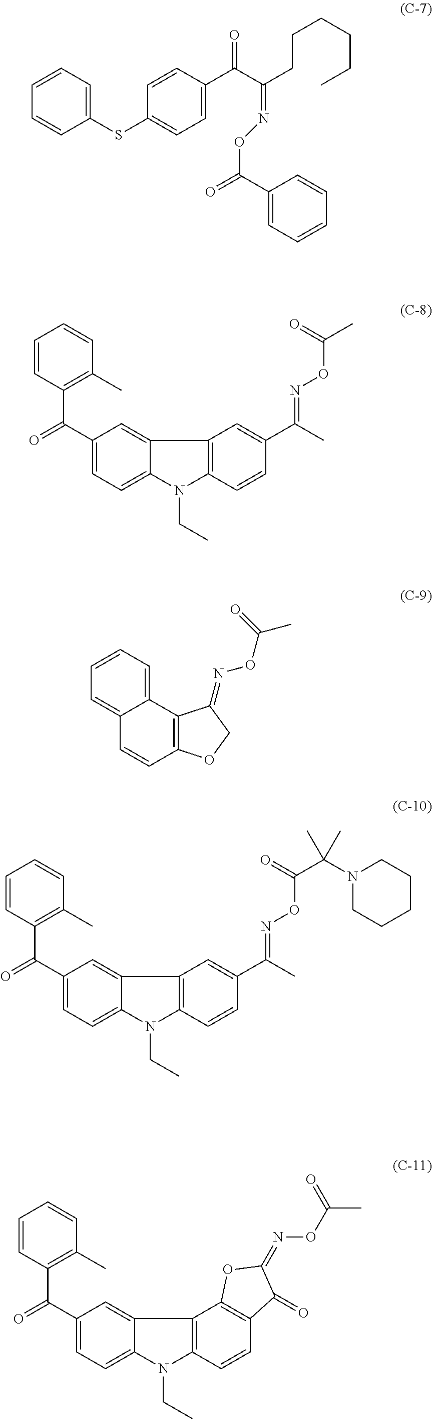 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

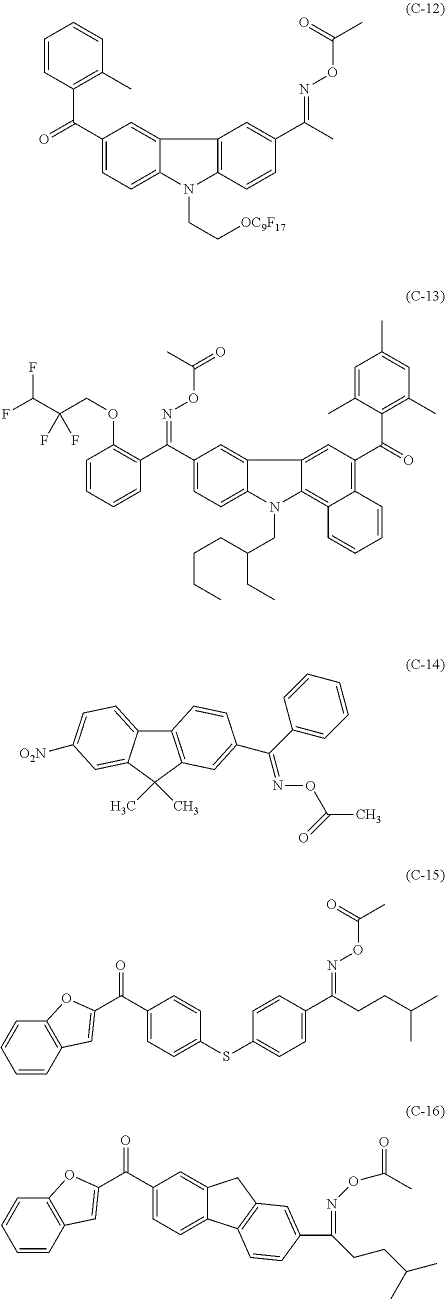

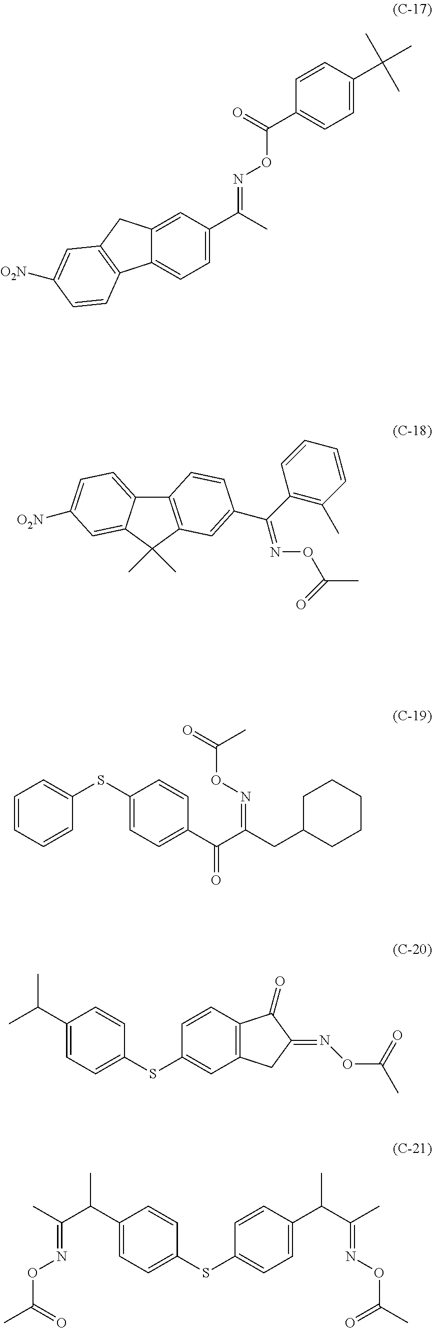

In the present invention, as the photopolymerization initiator, it is also preferable that a photopolymerization initiator A1 having a light absorption coefficient of more than 1.0×10² mL/g·cm at a wavelength of 365 nm in methanol, and a photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol are used in combination. According to this aspect, the coloring composition is easily cured sufficiently by exposure, high flatness is obtained in low-temperature process (for example, a process at a temperature of 150° C. or lower, preferably a temperature of 120° C. or lower, throughout entire steps), and a pixel having excellent characteristics such as light resistance and moisture resistance can be formed. As the photopolymerization initiator A1 and the photopolymerization initiator A2, compounds having the above-described light absorption coefficient are preferably selected and used from the above-described compounds.

In the present invention, the light absorption coefficient of a photopolymerization initiator at the above-described wavelength is a value measured as follows. That is, the light absorption coefficient is obtained by preparing a measurement solution by dissolving the photopolymerization initiator in methanol, and measuring absorbance of the measurement solution. Specifically, the measurement solution is put into a glass cell having a width of 1 cm, absorbance is measured using a UV-Vis-NIR spectrometer (Cary 5000) manufactured by Agilent Technologies Inc., and the light absorption coefficient (mL/g·cm) at a wavelength of 365 nm and a wavelength of 254 nm is obtained by applying the following expression.

$$ε = \frac{A}{cl}$$

In the expression, ε represents a light absorption coefficient (mL/g·cm), A represents an absorbance, c represents a concentration (g/mL) of the photopolymerization initiator, and 1 represents an optical path length (cm).

The light absorption coefficient of the photopolymerization initiator A1 at a wavelength of 365 nm in methanol is preferably 1.0×10³ mL/g·cm or more, more preferably 2.0×10³ mL/g·cm or more, still more preferably 3.0×10³ mL/g·cm or more, even more preferably 5.0×10³ mL/g·cm or more, and particularly preferably 1.0×10⁴ mL/g·cm or more.

In addition, the light absorption coefficient of the photopolymerization initiator A1 to light having a wavelength of 254 nm in methanol is preferably 1.0×10³ mL/g·cm or more, more preferably 1.5×10³ mL/g·cm or more, still more preferably 3.0×10³ mL/g·cm or more, and even more preferably 1.0×10⁴ mL/g·cm or more. The upper limit thereof is preferably 1.0×10⁵ mL/g·cm or less, more preferably 9.5×10⁴ mL/g·cm or less, and still more preferably 8.0×10⁴ mL/g·cm or less.

The photopolymerization initiator A1 is preferably the oxime compound, the aminoalkylphenone compound, or the acylphosphine compound, and more preferably the oxime compound or the aminoalkylphenone compound. In addition, in a case where the oxime compound is used as the photopolymerization initiator A1, higher sensitivity is obtained. In addition, in a case where the aminoalkylphenone compound is used as the photopolymerization initiator A1, the temporal stability of the coloring composition is more preferable.

Specific examples of the photopolymerization initiator A1 include the compound (C-7), the compound (C-8), the compound (C-13), and the compound (C-14), described in the specific examples of the oxime compound above. Examples of a commercially available product thereof include Irgacure OXE01 and Irgacure OXE02, which are oxime compounds manufactured by BASF; Omnirad 819, which is an acylphosphine compound manufactured by IGM Resins B.V.; and Omnirad 379, which is an aminoalkylphenone compound manufactured by IGM Resins B.V.

The light absorption coefficient of the photopolymerization initiator A2 at a wavelength of 365 nm in methanol is 1.0×10² mL/g·cm or less, preferably 10 to 1.0×10² mL/g·cm, and more preferably 20 to 1.0×10² mL/g·cm.

In addition, a difference between the light absorption coefficient of the photopolymerization initiator A1 at a wavelength of 365 nm in methanol and the light absorption coefficient of the photopolymerization initiator A2 at a wavelength of 365 nm in methanol is preferably 0.5×10² mL/g·cm or more, more preferably 1.0×10³ mL/g·cm or more, and still more preferably 1.5×10² mL/g·cm or more. The upper limit thereof is preferably 5.0×10⁴ mL/g·cm or less, more preferably 3.0×10⁴ mL/g·cm or less, and still more preferably 2.0×10⁴ mL/g·cm or less.

In addition, the light absorption coefficient of the photopolymerization initiator A2 at a wavelength of 254 nm in methanol is 1.0×10³ mL/g·cm or more, preferably 1.0×10³ to 1.0×10⁶ mL/g·cm, and more preferably 5.0×10³ to 1.0×10⁵ mL/g·cm.

As the photopolymerization initiator A2, the hydroxyalkylphenone compound, the phenylglyoxylate compound, or the acylphosphine compound is preferable, the hydroxyalkylphenone compound or the phenylglyoxylate compound is more preferable, and the hydroxyalkylphenone compound is still more preferable. In addition, as the hydroxyalkylphenone compound, the above-described compound represented by Formula (V) is preferable. Specific examples of the photopolymerization initiator A2 include the compounds having the structures shown as specific examples of the compound represented by Formula (V) described above. In addition, examples of a commercially available product of the photopolymerization initiator A2 include Omnirad 184 and Omnirad 2959, which are hydroxyalkylphenone compounds manufactured by IGM Resins B.V.

As a combination of the photopolymerization initiator A1 and the photopolymerization initiator A2, a combination in which the photopolymerization initiator A1 is the aminoalkylphenone compound or the oxime compound and the photopolymerization initiator A2 is the hydroxyalkylphenone compound is preferable; and a combination in which the photopolymerization initiator A1 is the aminoalkylphenone compound or the oxime compound and the photopolymerization initiator A2 is the compound represented by Formula (V) described above is more preferable.

A content of the photopolymerization initiator in the total solid content of the coloring composition is preferably 1 to 20 mass %. The lower limit thereof is preferably 3 mass % or more and more preferably 5 mass % or more. The upper limit thereof is preferably 15 mass % or less and more preferably 12.5 mass % or less. The photopolymerization initiator may be used alone or in combination of two or more kinds thereof. In a case where two or more kinds thereof are used in combination, the total amount thereof is preferably within the above-described range.

In the coloring composition according to the embodiment of the present invention, in a case where the above-described photopolymerization initiator A1 is used as the photopolymerization initiator, the content of the photopolymerization initiator A1 in the total solid content of the coloring composition is preferably 1 to 15 mass %. The lower limit thereof is preferably 3 mass % or more and more preferably 5 mass % or more. The upper limit thereof is preferably 12.5 mass % or less and more preferably 10 mass % or less.

In the coloring composition according to the embodiment of the present invention, in a case where the above-described photopolymerization initiator A2 is used as the photopolymerization initiator, the content of the photopolymerization initiator A2 in the total solid content of the coloring composition is preferably 1 to 10 mass %. The lower limit thereof is preferably 2 mass % or more and more preferably 3 mass % or more. The upper limit thereof is preferably 7.5 mass % or less and more preferably 5.0 mass % or less.

In the coloring composition according to the embodiment of the present invention, in a case where the above-described photopolymerization initiator A1 and the above-described photopolymerization initiator A2 are used as the photopolymerization initiator, it is preferable that the coloring composition according to the embodiment of the present invention contains 20 to 200 parts by mass of the photopolymerization initiator A2 with respect to 100 parts by mass of the photopolymerization initiator A1. The upper limit thereof is preferably 175 parts by mass or less and more preferably 150 parts by mass or less. The lower limit thereof is preferably 25 parts by mass or more and more preferably 30 parts by mass or more. According to this aspect, a cured film having excellent characteristics such as light resistance can be formed by low-temperature process (for example, process at a temperature of 150° C. or lower, preferably a temperature of 120° C. or lower, throughout entire steps). In a case where two or more kinds of the photopolymerization initiators A1 and two or more kinds of the photopolymerization initiators A2 are used in combination, it is preferable that the total amount of each satisfies the above-described requirements.

In the coloring composition according to the embodiment of the present invention, in a case where the above-described photopolymerization initiator A1 and the above-described photopolymerization initiator A2 are used as the photopolymerization initiator, the total content of the photopolymerization initiator A1 and the photopolymerization initiator A2 in the total solid content of the coloring composition is preferably 1 to 20 mass %. The lower limit thereof is preferably 3 mass % or more and more preferably 5 mass % or more. The upper limit thereof is preferably 15 mass % or less and more preferably 12.5 mass % or less.

The coloring composition according to the embodiment of the present invention may contain a photopolymerization initiator (hereinafter, also referred to as other photopolymerization initiators) other than the photopolymerization initiator A1 and the photopolymerization initiator A2 as the photopolymerization initiator, but it is preferable that the coloring composition according to the embodiment of the present invention does not substantially contain other photopolymerization initiators. The case where the coloring composition according to the embodiment of the present invention does not substantially contain other photopolymerization initiators means that the content of other photopolymerization initiators is 1 part by mass or less, more preferably 0.5 parts by mass or less, still more preferably 0.1 parts by mass or less, and even more preferably 0 parts by mass with respect to 100 parts by mass of the total amount of the photopolymerization initiator A1 and the photopolymerization initiator A2.

### <<Compound Having Cyclic Ether Group>>

The coloring composition according to the embodiment of the present invention can contain a compound having a cyclic ether group. Examples of the cyclic ether group include an epoxy group and an oxetanyl group, and an epoxy group is preferable. Examples of the compound having a cyclic ether group include a compound having 1 to 100 cyclic ether groups in one molecule. The upper limit of the number of cyclic ether groups may be, for example, 10 or less or 5 or less. The lower limit of the number of cyclic ether groups is preferably 2 or more.

The compound having a cyclic ether group may be a low-molecular-weight compound (for example, having a molecular weight of less than 1,000) or a high-molecular-weight compound (macromolecule) (for example, having a molecular weight of 1,000 or more, and in a case of a resin, having a weight-average molecular weight of 1,000 or more). The weight-average molecular weight of the cyclic ether group is preferably 200 to 100,000 and more preferably 500 to 50,000. The upper limit of the weight-average molecular weight is preferably 10,000 or less, more preferably 5,000 or less, and still more preferably 3,000 or less. In the present specification, a resin-type compound having a cyclic ether group (resin having a cyclic ether group) is a component corresponding to the resin. Examples of the resin-type compound having a cyclic ether group include a resin including a repeating unit having a cyclic ether group.

As the compound having a cyclic ether group, the compounds described in paragraph Nos. 0034 to 0036 of JP2013-011869A, the compounds described in paragraph Nos. 0147 to 0156 of JP2014-043556A, the compounds paragraph Nos. 0085 to 0092 of JP2014-089408A, and the compounds described in JP2017-179172A can also be used.

Examples of a commercially available product of the compound having a cyclic ether group include DENACOL EX-212L, EX-212, EX-214L, EX-214, EX-216L, EX-216, EX-321L, EX-321, EX-850L, and EX-850 (all of which are manufactured by Nagase ChemteX Corporation); ADEKA RESIN EP-4000S, EP-4003S, EP-4010S, and EP-4011S (all of which are manufactured by ADEKA Corporation); NC-2000, NC-3000, NC-7300, XD-1000, EPPN-501, and EPPN-502 (all of which are manufactured by ADEKA Corporation); CELLOXIDE 2021P, CELLOXIDE 2081, CELLOXIDE 2083, CELLOXIDE 2085, EHPE3150, EPOLEAD PB 3600, and PB 4700 (all of which are manufactured by Daicel Corporation); CYCLOMER P ACA 200M, ACA 230AA, ACA Z250, ACA Z251, ACA Z300, and ACA Z320 (all of which are manufactured by Daicel Corporation); jER 1031S, jER 157S65, jER 152, jER 154, and jER 157S70 (all of which are manufactured by Mitsubishi Chemical Corporation); ARON OXETANE OXT-121, OXT-221, OX-SQ, and PNOX (all of which are manufactured by TOAGOSEI CO., LTD.); ADEKA GLYCILOL ED-505 (manufactured by ADEKA Corporation, epoxy group-containing monomer); MARPROOF G-0150M, G-0105SA, G-0130SP, G-0250SP, G-1005S, G-1005SA, G-1010S, G-2050M, G-01100, and G-01758 (manufactured by NOF Corporation, epoxy group-containing polymer); OXT-101, OXT-121, OXT-212, and OXT-221 (all of which are manufactured by TOAGOSEI CO., LTD., oxetanyl group-containing monomer); and OXE-10 and OXE-30 (both of which are manufactured by OSAKA ORGANIC CHEMICAL INDUSTRY LTD., oxetanyl group-containing monomer).

A content of the compound having a cyclic ether group in the total solid content of the coloring composition is preferably 0.1 to 40 mass %. The lower limit thereof is preferably 1 mass % or more and more preferably 2 mass % or more. The upper limit thereof is preferably 30 mass % or less and more preferably 20 mass % or less. In addition, the content of the compound having a cyclic ether group is preferably 1 to 400 parts by mass, more preferably 1 to 100 parts by mass, and still more preferably 1 to 50 parts by mass with respect to 100 parts by mass of the polymerizable monomer. The compound having a cyclic ether group may be used alone or in combination of two or more kinds thereof. In a case where two or more kinds thereof are used in combination, the total amount thereof is preferably within the above-described range.

### <<Pigment Derivative>>

The coloring composition according to the embodiment of the present invention can contain a pigment derivative. Examples of the pigment derivative include a compound having a structure in which an acid group or a basic group is bonded to a coloring agent skeleton. The pigment derivative is used, for example, as a dispersion aid. The dispersion aid is a material for increasing dispersibility of the pigment in the coloring composition.

Examples of the coloring agent skeleton constituting the pigment derivative include a quinoline coloring agent skeleton, a benzimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton.

Examples of the acid group include a carboxy group, a sulfo group, a phosphoric acid group, a boronic acid group, a carboxylic acid amide group, a sulfonic acid amide group, an imidic acid group, and salts of these group. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. As the carboxylic acid amide group, a group represented by —NHCOR^{X1} is preferable. As the sulfonic acid amide group, a group represented by —NHSO₂R^{X2} is preferable. As the imidic acid group, a group represented by —SO₂NHSO₂R^{X3}, —CONHSO₂R^{X4}, —CONHCOR^{X5}, or —SO₂NHCOR^{X6} is preferable, and —SO₂NHSO₂R^{X3} is more preferable. R^{X1} to R^{X6} each independently represent an alkyl group or an aryl group. The alkyl group and the aryl group represented by R^{X1} to R^{X6} may have a substituent. As the substituent, a halogen atom is preferable and a fluorine atom is more preferable.

Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be used. The maximum value (εmax) of the molar absorption coefficient of the transparent pigment derivative in a wavelength region of 400 to 700 nm is preferably 3,000 L·mol⁻¹·cm⁻¹ or less, more preferably 1,000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later; compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A; diketopyrrolopyrrole compounds having a thiol linking group, described in WO2020/002106A; and benzimidazolone compounds and salt thereof, described in JP2018-168244A.

A content of the pigment derivative is preferably 0.1 to 30 parts by mass with respect to 100 parts by mass of the pigment. The lower limit of this range is more preferably 0.25 parts by mass or more, still more preferably 0.5 parts by mass or more, particularly preferably 0.75 parts by mass or more, and most preferably 1 part by mass or more. In addition, the upper limit of this range is more preferably 25 parts by mass or less, still more preferably 20 parts by mass or less, and particularly preferably 15 parts by mass or less. In a case where the content of the pigment derivative is within the above-described range, the storage stability of the coloring composition can be further improved. The pigment derivative may be used alone or in combination of two or more kinds thereof. In a case where two or more kinds thereof are used in combination, the total amount thereof is preferably within the above-described range.

### <<Polyalkyleneimine>>

The coloring composition according to the embodiment of the present invention can also contain polyalkyleneamine. The polyalkyleneamine is used, for example, as a dispersion aid. The dispersion aid is a material for increasing dispersibility of the pigment in the coloring composition. The polyalkyleneamine is a polymer obtained by a ring-opening polymerization of alkyleneimine. The polyalkyleneamine is preferably a polymer having a branched structure including each of a primary amino group, a secondary amino group, and a tertiary amino group. The number of carbon atoms in the alkyleneimine is preferably 2 to 6, more preferably 2 to 4, still more preferably 2 or 3, and particularly preferably 2.

A molecular weight of the polyalkyleneamine is preferably 200 or more and more preferably 250 or more. The upper limit thereof is preferably 100,000 or less, more preferably 50,000 or less, still more preferably 10,000 or less, and particularly preferably 2,000 or less. With regard to the value of the molecular weight of the polyalkyleneamine, in a case where the molecular weight can be calculated from a structural formula, the molecular weight of the polyalkyleneamine is a value calculated from the structural formula. On the other hand, in a case where the molecular weight of the specific amine compound cannot be calculated from the structural formula or is difficult to calculate, a value of a number-average molecular weight measured by a boiling point increase method is used. In addition, even in a case where the molecular weight of the polyalkyleneamine cannot be measured by the boiling point increase method or is difficult to be measured, a value of a number-average molecular weight measured by a viscosity method is used. In addition, in a case where the molecular weight of the polyalkyleneamine cannot be measured by the viscosity method or is difficult to be measured by the viscosity method, a value of a number-average molecular weight in terms of polystyrene through measurement by a gel permeation chromatography (GPC) method is used.

An amine value of the polyalkyleneamine is preferably 5 mmol/g or more, more preferably 10 mmol/g or more, and still more preferably 15 mmol/g or more.

Specific examples of the alkyleneimine include ethyleneimine, propyleneimine, 1,2-butyleneimine, and 2,3-butyleneimine, and ethyleneimine or propyleneimine is preferable and ethyleneimine is more preferable. The polyalkyleneamine is particularly preferably polyethyleneimine. In addition, the polyethyleneimine preferably includes the primary amino group in an amount of 10 mol % or more, more preferably includes the primary amino group in an amount of 20 mol % or more, and still more preferably includes the primary amino group in an amount of 30 mol % or more with respect to the total of the primary amino group, the secondary amino group, and the tertiary amino group. Examples of a commercially available product of the polyethyleneimine include EPOMIN SP-003, SP-006, SP-012, SP-018, SP-200, and P-1000 (all of which are manufactured by NIPPON SHOKUBAI CO., LTD.).

A content of the polyalkyleneamine in the total solid content of the coloring composition is preferably 0.1 to 5 mass %. The lower limit thereof is preferably 0.2 mass % or more, more preferably 0.5 mass % or more, and still more preferably 1 mass % or more. The upper limit thereof is preferably 4.5 mass % or less, more preferably 4 mass % or less, and still more preferably 3 mass % or less. In addition, the content of the polyalkyleneamine is preferably 0.5 to 20 parts by mass with respect to 100 parts by mass of the pigment. The lower limit thereof is preferably 0.6 parts by mass or more, more preferably 1 part by mass or more, and still more preferably 2 parts by mass or more. The upper limit thereof is preferably 10 parts by mass or less and more preferably 8 parts by mass or less. The polyalkyleneamine may be used alone or in combination of two or more kinds thereof. In a case where two or more kinds thereof are used, the total amount thereof is preferably within the above-described range.

### <<Curing Accelerator>>

For the purpose of promoting the reaction of polymerizable monomers or lowering a curing temperature, a curing accelerator may be added to the coloring composition according to the embodiment of the present invention. Examples of the curing accelerator include a polyfunctional thiol compound having two or more mercapto groups in a molecule. The polyfunctional thiol compound may also be added for the purpose of improving stability, odor, resolution, developability, adhesiveness, or the like. In addition, as the curing accelerator, a methylol-based compound (for example, the compounds exemplified as a crosslinking agent in paragraph No. 0246 of JP2015-034963A), amines, phosphonium salts, amidine salts, and amide compounds (each of which is the curing agent described in, for example, paragraph No. 0186 of JP2013-041165A), base generators (for example, the ionic compounds described in JP2014-055114A), cyanate compounds (for example, the compounds described in paragraph No. 0071 of JP2012-150180A), alkoxysilane compounds (for example, the alkoxysilane compounds having an epoxy group, described in JP2011-253054A), onium salt compounds (for example, the compounds exemplified as an acid generator in paragraph No. 0216 of JP2015-034963A, and the compounds described in JP2009-180949A), or the like can also be used. A content of the curing accelerator in the total solid content of the coloring composition is preferably 0.3 to 8.9 mass % and more preferably 0.8 to 6.4 mass %.

### <<Silane Coupling Agent>>

The coloring composition according to the embodiment of the present invention can contain a silane coupling agent. As the silane coupling agent, a silane compound having at least two kinds of functional groups having different reactivity in one molecule is preferable. The silane coupling agent is preferably a silane compound having at least one group selected from a vinyl group, an epoxy group, a styrene group, a methacryl group, an amino group, an isocyanurate group, a ureido group, a mercapto group, a sulfide group, or an isocyanate group, and an alkoxy group. Specific examples of the silane coupling agent include N-2-(aminoethyl)-3-aminopropyl methyldimethoxysilane (KBM-602, manufactured by Shin-Etsu Chemical Co., Ltd.), N-2-(aminoethyl)-3-aminopropyl trimethoxysilane (KBM-603, manufactured by Shin-Etsu Chemical Co., Ltd.), 3-aminopropyl trimethoxysilane (KBM-903, manufactured by Shin-Etsu Chemical Co., Ltd.), 3-aminopropyl triethoxysilane (KBE-903, manufactured by Shin-Etsu Chemical Co., Ltd.), 3-methacryloxypropyl trimethoxysilane (KBM-503, manufactured by Shin-Etsu Chemical Co., Ltd.), and 3-glycidoxypropyl trimethoxysilane (KBM-403, manufactured by Shin-Etsu Chemical Co., Ltd.). With regard to details of the silane coupling agent, reference can be made to the description in paragraph Nos. 0155 to 0158 of JP2013-254047A, the contents of which are incorporated herein by reference. A content of the silane coupling agent in the total solid content of the coloring composition is preferably 0.001 to 20 mass %, more preferably 0.01 to 10 mass %, and still more preferably 0.1 mass % to 5 mass %. The coloring composition according to the embodiment of the present invention may contain one kind or two or more kinds of the silane coupling agents. In a case of containing two or more kinds thereof, the total amount thereof is preferably within the above-described range.

### <<Polymerization Inhibitor>>

The coloring composition according to the embodiment of the present invention can contain a polymerization inhibitor. Examples of the polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol), and an N-nitrosophenylhydroxylamine salt (an ammonium salt, a cerous salt, or the like). The content of the polymerization inhibitor in the total solid content of the coloring composition is preferably 0.0001 to 5 mass %. The coloring composition according to the embodiment of the present invention may contain one kind or two or more kinds of the polymerization inhibitors. In a case of containing two or more kinds thereof, the total amount thereof is preferably within the above-described range.

### <<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd.), Tinuvin series and Uvinul series manufactured by BASF, and Sumisorb series manufactured by Sumika Chemtex Co., Ltd. In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B, compounds described in paragraph Nos. 0059 to 0076 of WO2016/181987A, and thioaryl group-substituted benzotriazole type ultraviolet absorbers described in WO2020/137819A can also be used. A content of the ultraviolet absorber in the total solid content of the coloring composition is preferably 0.1 to 10 mass %, more preferably 0.1 to 5 mass %, and particularly preferably 0.1 to 3 mass %. The coloring composition according to the embodiment of the present invention may contain only one kind of the ultraviolet absorber, or may contain two or more kinds thereof. In a case of containing two or more kinds thereof, the total amount thereof is preferably within the above-described range.

### <<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, or a silicone-based surfactant can be used. The surfactant is preferably a fluorine-based surfactant or a silicone-based surfactant, and more preferably a silicone-based surfactant. Examples of the surfactant include surfactants described in paragraph Nos. 0238 to 0245 of WO2015/166779A, the contents of which are incorporated herein by reference.

The fluorine content in the fluorine-based surfactant is suitably 3 to 40 mass %, and more preferably 5 to 30 mass % and particularly preferably 7% to 25 mass %. The fluorine-based surfactant in which the fluorine content is within the above-described range is effective in terms of the evenness of the thickness of the coating film or liquid saving property, and the solubility of the surfactant in the coloring composition is also favorable.

Examples of the fluorine-based surfactant include surfactants described in paragraph Nos. 0060 to 0064 of JP2014-041318A (paragraph Nos. 0060 to 0064 of the corresponding WO2014/017669A) and the like, surfactants described in paragraph Nos. 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, R-30, F-437, F-475, F-477, F-479, F-482, F-554, F-555-A, F-556, F-557, F-558, F-559, F-560, F-561, F-565, F-563, F-568, F-575, F-780, EXP, MFS-330, R-01, R-40, R-40-LM, R-41, R-41-LM, RS-43, R-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FL, 710FM, 710FS, and FTX-218 (manufactured by NEOS COMPANY LIMITED).

As the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

It is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

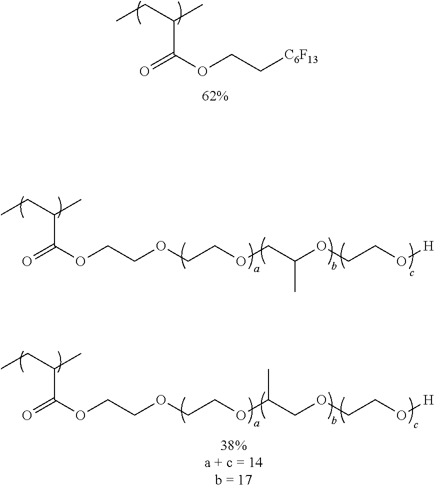

A weight-average molecular weight of the above-described compound is preferably 3,000 to 50,000 and, for example, 14,000. In the compound, “%” representing the proportion of a repeating unit is mol %.

As the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

From the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

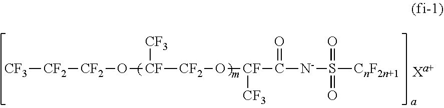

In Formula (fi-1), m represents 1 or 2, n represents an integer of 1 to 4, a represents 1 or 2, and X^{a+} represents an a-valent metal ion, a primary ammonium ion, a secondary ammonium ion, a tertiary ammonium ion, a quaternary ammonium ion, or NH₄⁺.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Japan Ltd.), NCW-101, NCW-1001, and NCW-1002 (all of which are manufactured by Wako Pure Chemical Corporation), PIONIN D-6112, D-6112-W, and D-6315 (all of which are manufactured by Takemoto Oil & Fat Co., Ltd.), and OLFINE E1010 and SURFYNOL 104, 400, and 440 (all of which are manufactured by Nissin Chemical Co., Ltd.).

Examples of the silicone-based surfactant include: DC3PA, SH7PA, DC11PA, SH21PA, SH28PA, SH29PA, SH30PA, SH8400, SH 8400 FLUID, FZ-2122, 67 Additive, 74 Additive, M Additive, and SF 8419 OIL (all of which are manufactured by Dow·TORAY); TSF-4300, TSF-4445, TSF-4460, and TSF-4452 (all of which are manufactured by Momentive Performance Materials Inc.); KP-341, KF-6000, KF-6001, KF-6002, and KF-6003 (all of which are manufactured by Shin-Etsu Chemical Co., Ltd.); and BYK-307, BYK-322, BYK-323, BYK-330, BYK-333, BYK-3760, and BYK-UV3510 (all of which are manufactured by BYK Chemie). In addition, as the silicone-based surfactant, a compound having the following structure can also be used.

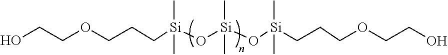

The content of the surfactant in the total solid content of the coloring composition is preferably 0.001 mass % to 5.0 mass % and more preferably 0.005 to 3.0 mass %. The coloring composition according to the embodiment of the present invention may contain one kind or two or more kinds of the surfactants. In a case of containing two or more kinds thereof, the total amount thereof is preferably within the above-described range.

### <<Other Additives>>

Various additives such as a filler, an adhesion promoter, an antioxidant, and an aggregation inhibitor can be blended into the coloring composition according to the embodiment of the present invention, as desired. Examples of these additives include the additives described in paragraph Nos. 0155 and 0156 of JP2004-295116A, the contents of which are incorporated herein by reference. In addition, as the antioxidant, for example, a phenol compound, a phosphorus-based compound (for example, compounds described in paragraph No. 0042 of JP2011-090147A), a thioether compound, or the like can be used. Examples of a commercially available product thereof include ADK STAB series (AO-20, AO-30, AO-40, AO-50, AO-50F, AO-60, AO-60G, AO-80, AO-330, and the like) manufactured by ADEKA Corporation. In addition, as the antioxidant, polyfunctional hindered amine antioxidants described in WO2017/006600A, antioxidants described in WO2017/164024A, and antioxidants described in paragraph Nos. 0023 to 0048 of JP6268967B can also be used. The antioxidant may be used alone or in combination of two or more kinds thereof. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° ° C. to 250° C. or heating the compound at 80° C. to 200° C. in the presence of an acid or base catalyst so that the compound functions as an antioxidant. Specific examples of the potential antioxidant include compounds described in WO2014/021023A, WO2017/030005A, and JP2017-008219A. Examples of a commercially available product thereof include ADEKA ARKLS GPA-5001 (manufactured by ADEKA Corporation). In addition, the coloring composition according to the embodiment of the present invention can contain sensitizers or light stabilizers described in paragraph 0078 of JP2004-295116A, thermal polymerization inhibitors described in paragraph 0081 of the same publication, or storage stabilizers described in paragraph No. 0242 of JP2018-091940A.

From the viewpoint of environmental regulation, the use of perfluoroalkyl sulfonic acid and a salt thereof and use of perfluoroalkyl carboxylic acid and a salt thereof may be restricted. In the coloring composition according to the embodiment of the present invention, in a case of reducing a content of the above-described compounds, the content of the perfluoroalkyl sulfonic acid (particularly, perfluoroalkyl sulfonic acid in which a perfluoroalkyl group has 6 to 8 carbon atoms) and a salt thereof and the perfluoroalkyl carboxylic acid (particularly, perfluoroalkyl carboxylic acid in which a perfluoroalkyl group has 6 to 8 carbon atoms) and a salt thereof is preferably in a range of 0.01 ppb to 1,000 ppb, more preferably 0.05 ppb to 500 ppb, and still more preferably 0.1 ppb to 300 ppb with respect to the total solid content of the coloring composition. The coloring composition according to the embodiment of the present invention may be substantially free of the perfluoroalkyl sulfonic acid and a salt thereof and the perfluoroalkyl carboxylic acid and a salt thereof. For example, by using a compound which can substitute for the perfluoroalkyl sulfonic acid and a salt thereof and the perfluoroalkyl carboxylic acid and a salt thereof, a coloring composition which is substantially free of the perfluoroalkyl sulfonic acid and a salt thereof and the perfluoroalkyl carboxylic acid and a salt thereof may be selected. Examples of the compound which can substitute for the regulated compounds include a compound which is excluded from the regulation due to difference in number of carbon atoms of the perfluoroalkyl group. However, the above-described contents do not prevent the use of perfluoroalkyl sulfonic acid and a salt thereof and use of perfluoroalkyl carboxylic acid and a salt thereof. The coloring composition according to the embodiment of the present invention may contain the perfluoroalkyl sulfonic acid and a salt thereof and the perfluoroalkyl carboxylic acid and a salt thereof within the maximum allowable range.

### <Storage Container>

A storage container of the coloring composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or coloring compositions. Examples of such a container include the containers described in JP2015-123351A. In addition, for the purpose of preventing metal elution from the container interior wall, improving storage stability of the coloring composition, and suppressing the alteration of components, it is also preferable that the container interior wall is formed of glass, stainless steel, or the like.

### <Method for Producing Coloring Composition>

The coloring composition according to the embodiment of the present invention can be produced by mixing the above-described components with each other. During the production of the coloring composition, all the components may be dissolved or dispersed in a solvent at the same time to produce the coloring composition. Optionally, two or more solutions or dispersion liquids in which the respective components are appropriately blended may be prepared, and the solutions or dispersion liquids may be mixed with each other during use (during application) to produce the coloring composition.

In addition, in the production of the coloring composition, a process of dispersing particles such as pigments may be included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the production of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE) and polyvinylidene fluoride (PVDF); a polyamide-based resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore diameter of the filter is preferably 0.01 to 7.0 μm, more preferably 0.01 to 3.0 μm, and still more preferably 0.05 to 0.5 μm. In a case where the pore diameter of the filter is within the above-described range, fine foreign matters can be reliably removed. With regard to the pore diameter value of the filter, reference can be made to a nominal value of filter manufacturers. As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. In this case, the filtration with each of the filters may be performed once or may be performed twice or more times. In addition, filters having different pore diameters within the above-described range may be combined. In addition, the filtration through the first filter may be performed with only a dispersion liquid, the other components may be mixed therewith, and then the filtration through the second filter may be performed.

### <Film>

The film according to the embodiment of the present invention is a film formed of the above-described coloring composition according to the embodiment of the present invention. The film according to the embodiment of the present invention can be used for a color filter or the like. Specifically, the film according to the embodiment of the present invention can be preferably used as a colored pixel of the color filter, and is more preferably used as a green pixel. A film thickness of the film according to the embodiment of the present invention can be adjusted according to the purpose, and is preferably 0.5 to 3.0 μm. The lower limit thereof is preferably 0.8 μm or more, more preferably 1.0 μm or more, and still more preferably 1.1 μm or more. The upper limit thereof is preferably 2.5 μm or less, more preferably 2.0 μm or less, and still more preferably 1.8 μm or less.

The maximum value of a transmittance of the film according to the embodiment of the present invention to light having a wavelength of 505 nm or more and less than 565 nm is preferably 60% or more, more preferably 65% or more, and still more preferably 70% or more.

In addition, an average transmittance of the film according to the embodiment of the present invention to light having a wavelength of 505 nm or more and less than 565 nm is preferably 55% or more, more preferably 60% or more, and still more preferably 65% or more.

In addition, a transmittance to light having a wavelength of 450 nm is preferably 10% or less, more preferably 5% or less, and still more preferably 2% or less.

In addition, an average transmittance to light having a wavelength of 400 nm or more and 450 nm or less is preferably 10% or less, more preferably 5% or less, and still more preferably 1% or less.

In addition, an average transmittance of the film according to the embodiment of the present invention to light having a wavelength of 540 nm or more and 610 nm or less is preferably 60% or less, more preferably 50% or less, and still more preferably 40% or less.

In addition, for the film according to the embodiment of the present invention, the maximal absorption wavelength is preferably in a wavelength range of 410 to 445 nm, more preferably in a wavelength range of 415 to 440 nm, and still more preferably in a wavelength range of 420 to 435 nm.

In addition, for the film according to the embodiment of the present invention, the wavelength at which the transmittance is 50% is preferably in a wavelength range of 505 to 535 nm and in a wavelength range of 540 to 585 nm. The wavelength on the short wavelength side, at which the transmittance is 50%, is preferably in a wavelength range of 510 to 530 nm and more preferably in a wavelength range of 515 to 525 nm. The wavelength on the long wavelength side, at which the transmittance is 50%, is preferably in a wavelength range of 545 to 580 nm, more preferably in a wavelength range of 555 to 570 nm, and still more preferably in a wavelength range of 555 to 565 nm.

In addition, for the film according to the embodiment of the present invention, it is preferable that chromaticity coordinates of the film in a case of being measured using a C light source in a CIE (International Commission on Illumination) xyz color system are x=0.170 to 0.300 and y=0.600 to 0.800. The x of the chromaticity coordinates of the above-described film is preferably 0.210 to 0.300 and more preferably 0.250 to 0.300. The y of the chromaticity coordinates of the above-described film is preferably 0.650 to 0.800 and more preferably 0.700 to 0.800. A film having such chromaticity coordinates is preferably used as a green pixel of a color filter.

### <Color Filter>

The color filter according to the embodiment of the present invention will be described. The color filter according to the embodiment of the present invention has the film according to the embodiment of the present invention. The color filter according to the embodiment of the present invention has the film according to the embodiment of the present invention preferably as a colored pixel of the color filter, and more preferably as a green pixel. The color filter according to the embodiment of the present invention can be used for a solid-state imaging element or a display device.

It is preferable that the color filter according to the embodiment of the present invention has a colored pixel having another hue in addition to the pixel of the film according to the embodiment of the present invention. Examples of colored pixels having other hues include a blue pixel, a red pixel, a yellow pixel, a magenta pixel, and a cyan pixel. Examples of a preferred aspect of the color filter according to the embodiment of the present invention include an aspect of having a red pixel, a blue pixel, and a green pixel which is composed of the film according to the embodiment of the present invention. The color filter may have a structure in which each colored pixel is embedded in a space partitioned in, for example, a lattice form by a partition wall. In this case, it is preferable that the partition wall has a lower refractive index than each colored pixel. In addition, the partition wall may be formed with a configuration described in US2018/0040656A.

The red pixel which is preferably used in combination with the pixel of the film according to the embodiment of the present invention preferably contains a red colorant. A content of the red colorant in colorants contained in the red pixel is preferably 30 mass % or more and more preferably 40 mass % or more. The upper limit of the content of the red colorant in colorants contained in the red pixel may be 100 mass %, 99 mass % or less, 95 mass % or less, or 90 mass % or less. In addition, the red pixel preferably contains 40 mass % or more of the red colorant, more preferably contains 50 mass % or more thereof, and still more preferably contains 60 mass % or more thereof. In addition, the upper limit of the content of the red colorant is preferably 80 mass % or less, more preferably 70 mass % or less, and still more preferably 60 mass % or less. Examples of the red colorant include red pigments such as C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297. Among these, C. I. Pigment Red 122, 177, 179, 202, 254, 264, 269, or 272 is preferable, C. I. Pigment Red 177, 179, 202, 254, 264, or 272 is more preferable, C. I. Pigment Red 177, 254, or 264 is still more preferable, and C. I. Pigment Red 177 is particularly preferable.

From the reason that the color separation from the green pixel can be enhanced, a content of C. I. Pigment Red 177 in the colorant is preferably 30 mass % or more, more preferably 50 mass % or more, and still more preferably 70 mass % or more. The upper limit thereof may be 100 mass % or less, 90 mass % or less, or 80 mass % or less.

From the reason that the color separation from the green pixel can be enhanced, the content of C. I. Pigment Red 177 in the red colorant is preferably 30 to 100 mass % or more, more preferably 50 to 100 mass % or more, and still more preferably 70 to 100 mass % or more. The red colorant is preferably substantially only the C. I. Pigment Red 177. In the present specification, the case where the red colorant is substantially only the C. I. Pigment Red 177 means that the content of C. I. Pigment Red 177 in the red colorant is 99 mass % or more, preferably 99.5 mass % or more, more preferably 99.9 mass % or more, and particularly preferably 100 mass %.

It is more preferable that the above-described red pixel further contains a yellow colorant in addition to the red colorant. A content of the yellow colorant is preferably 3 to 60 parts by mass, more preferably 5 to 50 parts by mass, and still more preferably 10 to 40 parts by mass with respect to 100 parts by mass of the red colorant. Examples of the yellow colorant include yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232, 233, 234, 235, and 236, and among these, C. I. Pigment Yellow 129, 138, 139, 150, or 185 is preferable.

With regard to the above-described red pixel, the maximum value of a transmittance to light having a wavelength of 400 to 550 nm is preferably 5% or less, more preferably 3% or less, and still more preferably 1% or less. In addition, an average transmittance to light having a wavelength of 400 to 550 nm is preferably 3% or less, more preferably 1% or less, and still more preferably 0.5% or less. In addition, the minimum value of a transmittance to light having a wavelength of 600 to 700 nm is preferably 10% or more, more preferably 25% or more, and still more preferably 40% or more. In addition, an average transmittance to light having a wavelength of 600 to 700 nm is preferably 80% or more, more preferably 90% or more, and still more preferably 95% or more.

In addition, for the red pixel, it is preferable that chromaticity coordinates of the film in a case of being measured using a C light source in a CIE (International Commission on Illumination) XYZ color system are x=0.640 to 0.710 and y=0.290 to 0.330. The x of the chromaticity coordinates of the red pixel is preferably 0.650 to 0.700 and more preferably 0.660 to 0.690. The y of the chromaticity coordinates of the red pixel is preferably 0.300 to 0.325 and more preferably 0.310 to 0.320.

The blue pixel which is preferably used in combination with the pixel of the film according to the embodiment of the present invention preferably contains a blue colorant. A content of the blue colorant in colorants contained in the blue pixel is preferably 40 mass % or more and more preferably 60 mass % or more. In addition, the blue pixel preferably contains 20 mass % or more of the blue colorant, more preferably contains 25 mass % or more thereof, and still more preferably contains 30 mass % or more thereof. The upper limit of the content of the blue colorant is preferably 80 mass % or less, more preferably 70 mass % or less, and still more preferably 60 mass % or less. Examples of the blue colorant include blue pigments such as C. I. Pigment Blue 1, 2, 15, 15:1, 15:2, 15:3, 15:4, 15:6, 16, 22, 29, 60, 64, 66, 79, 80, 87, and 88, and among these, C. I. Pigment Blue 15:6 is preferable.

It is more preferable that the above-described blue pixel further contains at least one selected from a violet colorant or a red colorant, in addition to the blue colorant. A content of the violet colorant is preferably 10 to 90 parts by mass, more preferably 20 to 75 parts by mass, and still more preferably 30 to 60 parts by mass with respect to 100 parts by mass of the blue colorant. Examples of the violet colorant include violet pigments such as C. I. Pigment Violet 1, 19, 23, 27, 32, 37, 42, 60, and 61, and xanthene compounds. Examples of the xanthene compound include salt-forming compounds obtained by reacting a resin having a cationic group in the side chain with a xanthene-based acid dye, which are described in paragraph Nos. 0025 to 0077 of JP2016-180834A.

With regard to the above-described blue pixel, the maximum value of a transmittance to light having a wavelength of 400 to 500 nm is preferably 50% or more, more preferably 60% or more, and still more preferably 70% or more. In addition, an average transmittance to light having a wavelength of 400 to 500 nm is preferably 40% or more, more preferably 50% or more, and still more preferably 60% or more. In addition, the minimum value of a transmittance to light having a wavelength of 550 to 700 nm is preferably 30% or less, more preferably 20% or less, and still more preferably 10% or less. In addition, an average transmittance to light having a wavelength of 550 to 700 nm is preferably 25% or less, more preferably 10% or less, and still more preferably 5% or less.

In addition, for the blue pixel, it is preferable that chromaticity coordinates of the film in a case of being measured using a C light source in a CIE (International Commission on Illumination) XYZ color system are x=0.130 to 0.160 and y=0.035 to 0.080. The x of the chromaticity coordinates of the blue pixel is preferably 0.135 to 0.155 and more preferably 0.140 to 0.150. The y of the chromaticity coordinates of the blue pixel is preferably 0.040 to 0.075 and more preferably 0.045 to 0.070.

### <Structure Body>

The structure body according to the embodiment of the present invention includes a green pixel formed of the above-described coloring composition according to the embodiment of the present invention, a red pixel, and a blue pixel. It is preferable that the green pixel has the spectral characteristics described in the section of the film according to the embodiment of the present invention. In addition, it is preferable that the red pixel and the blue pixel have the spectral characteristics described in the section of the color filter.

The red pixel contains a colorant including C. I. Pigment Red 177, and a content of the C. I. Pigment Red 177 in the colorant contained in the red pixel is preferably 30 mass % or more, more preferably 50 mass % or more, and still more preferably 70 mass % or more. The upper limit thereof may be 100 mass % or less, 90 mass % or less, or 80 mass % or less. In addition, from the reason that the color separation from the green pixel can be enhanced, the content of C. I. Pigment Red 177 in the red colorant contained in the red pixel is preferably 30 to 100 mass % or more, more preferably 50 to 100 mass % or more, and still more preferably 70 to 100 mass % or more. The red colorant is preferably substantially only the C. I. Pigment Red 177. In the present specification, the case where the red colorant is substantially only the C. I. Pigment Red 177 means that the content of C. I. Pigment Red 177 in the red colorant is 99 mass % or more, preferably 99.5 mass % or more, more preferably 99.9 mass % or more, and particularly preferably 100 mass %.

It is more preferable that the red pixel further contains a yellow colorant in addition to the red colorant. A content of the yellow colorant is preferably 3 to 60 parts by mass, more preferably 5 to 50 parts by mass, and still more preferably 10 to 40 parts by mass with respect to 100 parts by mass of the red colorant. Examples of the yellow colorant include the above-described yellow colorants.

### <Method for Forming Pixels>

A method for forming pixels will be described. The green pixel can be formed of, for example, the coloring composition according to the embodiment of the present invention.

The method for forming a pixel preferably includes a step of forming a coloring composition layer by applying a coloring composition to a support, a step of exposing the coloring composition layer in a patterned manner, and a step of developing the coloring composition layer after exposure. It is preferable that the formation of pixels is performed at a temperature of 150° C. or lower throughout the entire steps. In the present invention, “performing at a temperature of 150° C. or lower throughout the entire steps” means that all steps of forming pixels using the coloring composition are performed at a temperature of 150° C. or lower. In a case where a heating step is further provided after developing the coloring composition layer after exposure, it means that this heating step is also performed at a temperature of 150° C. or lower. Hereinafter, each step will be described in detail.

In the step of forming a coloring composition layer, the coloring composition is applied onto a support to form the coloring composition layer. Examples of the support include a glass substrate, a polycarbonate substrate, a polyester substrate, an aromatic polyamide substrate, a polyamide-imide substrate, and a polyimide substrate. An organic light emitting layer may be formed on these substrates. In addition, an undercoat layer may be provided on the substrate so as to improve adhesiveness to an upper layer, prevent the diffusion of substances, or planarize the surface. The undercoat layer can also be formed using, for example, a composition obtained by removing a colorant from the above-described coloring composition according to the embodiment of the present invention. A surface contact angle of the undercoat layer is preferably 20° to 70° in a case of being measured with diiodomethane. In addition, the surface contact angle of the base layer is preferably 30° to 80° in a case of being measured with water.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an ink jet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. A method for applying the ink jet is not particularly limited, and examples thereof include a method described in “Extension of Use of Ink Jet-Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case where pre-baking is performed, the pre-baking temperature is preferably 80° C. or lower, more preferably 70° C. or lower, still more preferably 60° C. or lower, and particularly preferably 50° C. or lower. The lower limit may be, for example, 40° C. or higher. The pre-baking time is preferably 10 to 3600 seconds. The pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. In addition, the upper limit of the maximum instantaneous illuminance is preferably 1,000,000,000 W/m² or less, more preferably 800,000,000 W/m² or less, and still more preferably 500,000,000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation amount (exposure amount) is, for example, preferably 0.03 to 2.5 J/cm². The lower limit thereof is preferably 0.05 J/cm² or more, more preferably 0.2 J/cm² or more, still more preferably 0.5 J/cm² or more, even more preferably 0.8 J/cm² or more, and even still more preferably 1.0 J/cm² or more. The upper limit thereof is preferably 2.0 J/cm² or less, and more preferably 1.5 J/cm² or less. In addition, the exposure illuminance can be appropriately set, and is preferably, for example, 50 mW/cm² to 10 W/cm². The lower limit of the exposure illuminance is preferably 500 mW/cm² or more, more preferably 800 mW/cm² or more, and still more preferably 1,000 mW/cm² or more. The upper limit of the exposure illuminance is preferably 10 W/cm² or less, more preferably 7 W/cm² or less, and still more preferably 5 W/cm² or less.

The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. Appropriate conditions of each of the oxygen concentration and the exposure illuminance may be combined, and for example, a combination of the oxygen concentration of 10% by volume and the illuminance of 1 W/cm², a combination of the oxygen concentration of 35% by volume and the illuminance of 2 W/cm², or the like is available.

In addition, it is also preferable to irradiate with light (preferably i-rays) having a wavelength of more than 350 nm and 380 nm or less with an exposure amount of 1 J/cm² or more for exposure. By exposing in this way, the coloring composition layer can be sufficiently cured, and a pixel having more excellent light resistance can be manufactured.

Next, the coloring composition layer after exposure is developed. That is, a non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferable. As the alkali developer, an aqueous alkaline solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle jetting the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is also preferable to carry out an additional exposure treatment or a heating treatment (post-baking) after carrying out drying. The additional exposure treatment or the post-baking is a curing treatment after development in order to complete curing.

In a case where the post-baking is performed, the heating temperature is preferably 150° C. or lower. The upper limit of the heating temperature is more preferably 120° C. or lower and still more preferably 100° C. or lower. The lower limit of the heating temperature is not particularly limited as long as the curing of the film can be promoted, but is preferably 50° C. or higher and more preferably 75° C. or higher. The heating time is preferably 1 minute or more, more preferably 5 minutes or more, and still more preferably 10 minutes or more. The upper limit thereof is not particularly limited, but from the viewpoint of productivity, 20 minutes or less is preferable. It is also preferable that the post-baking is performed in an atmosphere of an inert gas. According to this aspect, thermal polymerization can proceed with very high efficiency without being hindered by oxygen, and even in a case where a pixel is produced at a temperature of 150° C. or lower throughout the entire steps, it is possible to produce a pixel having high flatness and excellent characteristics such as light resistance. Examples of the inert gas include nitrogen gas, argon gas, and helium gas, and nitrogen gas is preferable. The oxygen concentration during post-baking is preferably 100 ppm or less.

In a case of performing the additional exposure treatment, it is preferable to irradiate with light having a wavelength of 254 to 350 nm for exposure. As a more preferred aspect, it is preferable that, in the step of exposing the coloring composition layer (exposure before development) in a patterned manner, the coloring composition layer is exposed by irradiating the coloring composition layer with light having a wavelength of more than 350 nm and 380 nm or less (preferably light having a wavelength of 355 to 370 nm and more preferably i-rays), and in the additional exposure treatment (exposure after development), the coloring composition layer after development is exposed by irradiating the coloring composition layer with light having a wavelength of 254 to 350 nm (preferably light having a wavelength of 254 nm). According to this aspect, the coloring composition layer can be moderately cured at the first exposure (exposure before development), and the entire composition layer can be cured almost completely at the next exposure (exposure after development). As a result, the coloring composition layer can be sufficiently cured even under low temperature conditions, and it is possible to form a pixel having excellent characteristics such as light resistance, adhesiveness, and rectangularness. In a case where the exposure is performed in two stages as described above, in the coloring composition, it is preferable that a photopolymerization initiator including the photopolymerization initiator A1 having a light absorption coefficient of 1.0×10³ mL/g·cm or more at a wavelength of 365 nm in methanol and the photopolymerization initiator A2 having a light absorption coefficient of 1.0×10² mL/g·cm or less at a wavelength of 365 nm in methanol and having a light absorption coefficient of 1.0×10³ mL/g·cm or more at a wavelength of 254 nm in methanol is used as the photopolymerization initiator.

The exposure after development can be performed using, for example, an ultraviolet photoresist curing device. The light having a wavelength of 254 to 350 nm and other light (for example, i-rays) may irradiate from the ultraviolet photoresist curing device.

In addition, as an exposure source spectrum in a case of performing the additional exposure treatment, a continuous spectrum is preferable, and from the viewpoint of improving the light resistance of the obtained film and the adhesiveness with the substrate, it is preferable to have a spectral distribution of the spectrum different from the exposure before development, and examples thereof include the following radiation (a) to (c). Among these, from the viewpoint that the light resistance of the obtained film and the adhesiveness with the substrate can be improved at a higher level, the radiation (b) or (c) is preferable. In addition, in a case where the colorant includes a dye, since the dye generally absorbs ultraviolet rays or short-wavelength visible light to be photodecomposed, the radiation (c) having less high-intensity components on the short wavelength side is preferable.
(a) radiation having a spectral distribution of the spectrum different from the exposure before development, in which a peak intensity at a wavelength of 313 nm (j-rays) is ⅙ or more and less than ⅓ with respect to a peak intensity at a wavelength of 365 nm (i-rays)
(b) radiation having a spectral distribution of the spectrum different from the exposure before development, in which a peak intensity at a wavelength of 313 nm (j-rays) is ⅓ or more with respect to a peak intensity at a wavelength of 365 nm (i-rays); the upper limit of the peak intensity at such a wavelength of 313 nm is not particularly limited, but is preferably smaller than the peak intensity at a wavelength of 365 nm and more preferably ¾ or less with respect to the peak intensity at a wavelength of 365 nm.
(c) radiation having a spectral distribution of the spectrum different from the exposure before development and including a wavelength of 405 nm (h-rays) and a wavelength of 436 nm (g-rays), in which a peak intensity at a wavelength of 313 nm (j-rays) and a peak intensity at a wavelength of 365 nm (i-line) are ¼ or less, preferably 1/10 or less and more preferably 1/20 or less with respect to a smaller peak intensity of a peak intensity at the wavelength of 405 nm (h-rays) and a peak intensity at the wavelength of 436 nm (g-rays); the lower limit of the peak intensity at such a wavelength of 313 nm (j-rays) and a wavelength of 365 nm (i-rays) is not particularly limited.

In this case, as the exposure before development, radiation including a wavelength of 365 nm (i-rays), a wavelength of 405 nm (h-rays), and a wavelength of 436 nm (g-rays), in which a peak intensity at a wavelength of 313 nm (j-rays) is less than ⅙ with respect to a peak intensity at the wavelength of 365 nm (i-rays), is preferable.

For example, radiation exhibiting such spectral characteristics can be obtained using a light source exhibiting the above-described spectral characteristics or using radiation emitted from a high-pressure mercury lamp through an ultraviolet cut filter or a band pass filter.

The irradiation amount (exposure amount) in the exposure after development is preferably 0.03 to 4.0 J/cm² and more preferably 0.05 to 3.5 J/cm². The difference between the wavelength of the light used for the exposure before development and the wavelength of the light used for the exposure after development is preferably 200 nm or less and more preferably 100 to 150 nm.

### <Display Device>

A display device according to an embodiment of the present invention has the film according to the embodiment of the present invention. Examples of the display device include a liquid crystal display device or an organic electroluminescent display device. The definitions of display devices or the details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

In addition, the organic electroluminescent display device may be a micro display. A diagonal length of a display surface in the micro display can be, for example, 4 inches or less, 2 inches or less, 1 inch or less, or 0.2 inches or less. The application of the micro display is not particularly limited, and examples thereof include an electronic view finder, smart glasses, and a head-mounted display.

The organic electroluminescent display device may be an organic electroluminescent display device which has a light source composed of a white organic electroluminescent element. It is preferable that the white organic electroluminescent element has a tandem structure. The tandem structure of the organic electroluminescent element is described in, for example, JP2003-045676A, or pp. 326 to 328 of “Forefront of Organic EL Technology Development-Know-How Collection of High Brightness, High Precision, and Long Life” (Technical Information Institute, 2008). It is preferable that a spectrum of white light emitted from the organic EL element has high maximum emission peaks in a blue range (430 nm to 485 nm), a green range (530 nm to 580 nm), and a yellow range (580 nm to 620 nm). It is more preferable that the spectrum has a maximum emission peak in a red range (650 nm to 700 nm) in addition to the above-described emission peaks.

The organic electroluminescent display device may have a color filter. The color filter may be provided on the base layer. In addition, in an organic electroluminescent display device of a system in which a color filter and a white organic electroluminescent element are combined to extract light of three primary colors, a transparent pixel may be provided to use white light as it is for light emission. In this manner, brightness of the display device can also be increased. In addition, the organic electroluminescent display device may have a lens on the color filter. As a shape of the lens, various shapes derived by an optical system design can be taken, and examples thereof include a convex shape and a concave shape. For example, by taking a concave shape (concave lens), it is easy to improve light collecting property. In addition, the lens may be in direct contact with the color filter, or another layer such as an adhesion layer and a planarizing layer may be provided between the lens and the color filter. In addition, the lens can also be disposed and used in the manner described in WO2018/135189A.

### <Solid-State Imaging Element>

The coloring composition and film according to the embodiment of the present invention can also be used for a solid-state imaging element. The configuration of the solid-state imaging element is not particularly limited as long as the solid-state imaging element is configured so as to function as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the pixels of the color filter may be embedded in a space partitioned by a partition wall, for example, in a lattice form. In this case, it is preferable that the refractive index of the partition wall is lower than the refractive index of the pixel. Examples of an imaging apparatus having such a structure include the devices described in JP2012-227478A, JP2014-179577A, WO2018/043654A, and US2018/0040656A. An imaging apparatus including the solid-state imaging element can also be used as a vehicle camera or a surveillance camera, in addition to a digital camera or electronic apparatus (mobile phones or the like) having an imaging function.

### EXAMPLES

Hereinafter, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

### <Production of Pigment Dispersion Liquid>

### (Production of Pigment Dispersion Liquids P-G1 to P-G6, P-G9, P-G10, P-Gr1, and P-Gr2)

Pigments 1 to 6 shown in the following table, 1.5 parts by mass of a pigment derivative 1, 7.3 parts by mass of a dispersant 1, and 79.76 parts by mass of propylene glycol monomethyl ether acetate (PGMEA) were mixed and dispersed for 3 hours using a beads mill (zirconia beads having a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. The dispersion treatment was repeated 10 times to produce pigment dispersion liquids P-G1 to P-G6, P-G9, P-G10, P-Gr1, and P-Gr2, respectively.

### (Production of Pigment Dispersion Liquid P-G7)

Pigments 1 to 5 shown in the following table, 0.75 parts by mass of a pigment derivative 1, 0.75 parts by mass of a pigment derivative 2, 7.3 parts by mass of a dispersant 1, and 79.76 parts by mass of propylene glycol monomethyl ether acetate (PGMEA) were mixed and dispersed for 3 hours using a beads mill (zirconia beads having a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. The dispersion treatment was repeated 10 times to produce a pigment dispersion liquid P-G7.

### (Production of Pigment Dispersion Liquid P-G8)

Pigments 1 to 5 shown in the following table, 1.5 parts by mass of a pigment derivative 1, 7.3 parts by mass of a dispersant 1, 0.01 parts by mass of a compound A, and 79.76 parts by mass of propylene glycol monomethyl ether acetate (PGMEA) were mixed and dispersed for 3 hours using a beads mill (zirconia beads having a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. The dispersion treatment was repeated 10 times to produce a pigment dispersion liquid P-G8.

### Pigment Derivative 1: Compound Having the Following Structure

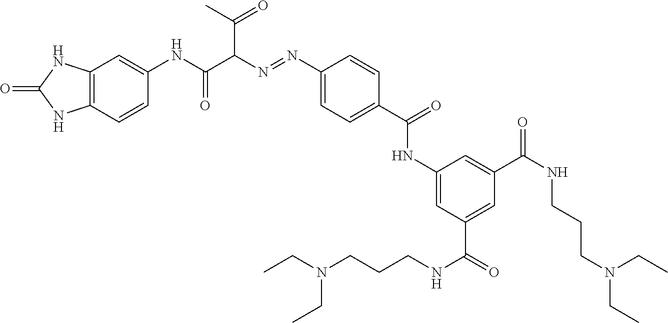 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

### Pigment Derivative 2: Compound Having the Following Structure

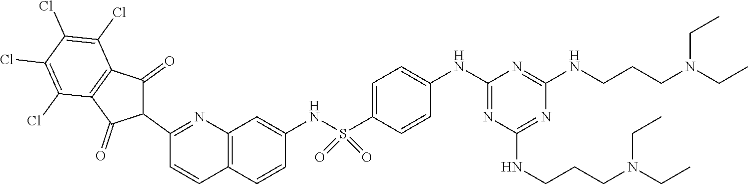 [SMILES: CCN(CC)CCCNc1nc(NCCCN(CC)CC)nc(Nc2ccc(S(=O)(=O)Nc3ccc4ccc(C5C(=O)c6c(Cl)c(Cl)c(Cl)c(Cl)c6C5=O)nc4c3)cc2)n1]

### Compound A: Compound Having the Following Structure

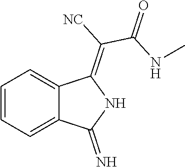 [SMILES: CNC(=O)/C(C#N)=C1\NC(=N)c2ccccc21]

Dispersant 1: resin having the following structure (a numerical value in parentheses of a main chain represents a molar ratio of each repeating unit, and a numerical value in parentheses of a side chain represents the repetition number of the repeating unit; weight-average molecular weight=20,000)

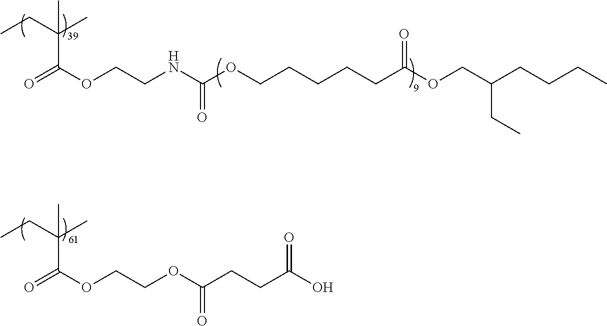

TABLE 1

| | Pigment 1 | | Pigment 2 | | Pigment 3 | | Pigment 4 | | Pigment 5 | | Pigment 6 | |
|---|---|---|---|---|---|---|---|---|---|---|---|---|
| | Type | Content | Type | Content | Type | Content | Type | Content | Type | Content | Type | Content |
| P-G1 | PG7 | 4.43 | PG36 | 2.02 | PY139 | 4.25 | PY150 | 0.54 | PY185 | 0.19 | | |
| P-G2 | PG7 | 2.77 | PG36 | 3.94 | PY139 | 3.30 | PY150 | 1.05 | PY185 | 0.36 | | |
| P-G3 | PG7 | 4.43 | PG58 | 2.02 | PY139 | 4.25 | PY150 | 0.54 | PY185 | 0.19 | | |
| P-G4 | PG7 | 4.43 | PG59 | 2.02 | PY139 | 4.25 | PY150 | 0.54 | PY185 | 0.19 | | |
| P-G5 | PG7 | 4.43 | PG59 | 2.02 | PY139 | 4.25 | PY129 | 0.54 | PY185 | 0.19 | | |
| P-G6 | PG7 | 4.43 | PG59 | 2.02 | PY139 | 4.25 | PY215 | 0.54 | PY185 | 0.19 | | |
| P-G7 | PG7 | 4.43 | PG36 | 2.02 | PY139 | 4.25 | PY150 | 0.54 | PY185 | 0.19 | | |
| P-G8 | PG7 | 4.43 | PG36 | 2.02 | PY139 | 4.25 | PY150 | 0.54 | PY185 | 0.19 | | |
| P-G9 | PG7 | 3.64 | PG36 | 1.30 | PY139 | 3.60 | PY150 | 0.54 | PY185 | 1.80 | PB15:4 | 0.55 |
| P-G10 | PG7 | 3.64 | PG36 | 1.30 | PY139 | 3.60 | PY150 | 0.54 | PY185 | 1.80 | PB15:3 | 0.55 |
| P-Gr1 | PG7 | 0.19 | PG58 | 6.26 | PY139 | 4.25 | PY138 | 0.54 | PY185 | 0.19 | | |
| P-Gr2 | PG7 | 3.00 | PG58 | 3.55 | PY139 | 4.25 | PY138 | 0.54 | PY185 | 0.09 | | |

PG7: Color Index Pigment Green 7
PG36: Color Index Pigment Green 36
PG58: Color Index Pigment Green 58
PG59: Color Index Pigment Green 59
PY139: Color Index Pigment Yellow 139
PY150: Color Index Pigment Yellow 150
PY129: Color Index Pigment Yellow 129
PY215: Color Index Pigment Yellow 215
PY138: Color Index Pigment Yellow 138
PY185: Color Index Pigment Yellow 185
PB15:3: Color index Pigment Blue 15:3
PB15:4: Color index Pigment Blue 15:4

### <Production of Coloring Composition>

Raw materials shown in the following tables were mixed and stirred, and the obtained mixture was filtered using a nylon filter (manufactured by Nihon Pall Corporation) having a pore diameter of 0.45 μm to produce a coloring composition. The unit of the numerical value described in the column of “Content” is part by mass.

TABLE 2

| | Pigment | | Photopolymerization | | | | Resin | | Polymerizable | | | | | | | |
|---|---|---|---|---|---|---|---|---|---|---|---|---|---|---|---|---|
| | derivative | | initiator | | | | solution | | monomer | | | | Surfactant | | Solvent | |
| | | Con- | | Con- | | Con- | | Con- | | Con- | | Con- | | Con- | | Con- |
| | Type | tent | Type 1 | tent | Type 2 | tent | Type | tent | Type 1 | tent | Type 2 | tent | Type | tent | Type | tent |
| Example 1 | P-G1 | 81.8 | I1 | 2.25 | I2 | 0.85 | R1 | 3.29 | M1 | 3.60 | M2 | 3.60 | G1 | 0.008 | S1 | 4.6 |
| Example 2 | P-G2 | 81.8 | I1 | 2.25 | I2 | 0.85 | R1 | 3.29 | M1 | 3.60 | M2 | 3.60 | G1 | 0.008 | S1 | 4.6 |
| Example 3 | P-G3 | 81.8 | I1 | 2.25 | I2 | 0.85 | R1 | 3.29 | M1 | 3.60 | M2 | 3.60 | G1 | 0.008 | S1 | 4.6 |
| Example 4 | P-G4 | 81.8 | I1 | 2.25 | I2 | 0.85 | R1 | 3.29 | M1 | 3.60 | M2 | 3.60 | G1 | 0.008 | S1 | 4.6 |
| Example 5 | P-G5 | 81.8 | I1 | 2.25 | I2 | 0.85 | R1 | 3.29 | M1 | 3.60 | M2 | 3.60 | G1 | 0.008 | S1 | 4.6 |
| Example 6 | P-G6 | 81.8 | I1 | 2.25 | I2 | 0.85 | R1 | 3.29 | M1 | 3.60 | M2 | 3.60 | G1 | 0.008 | S1 | 4.6 |
| Example 7 | P-G2 | 81.8 | I3 | 2.25 | — | — | R1 | 3.29 | M1 | 3.60 | M2 | 3.60 | G1 | 0.008 | S1 | 5.5 |
| Example 8 | P-G1 | 81.8 | I3 | 2.25 | I2 | 0.85 | R2 | 3.29 | M1 | 3.60 | M2 | 3.60 | G1 | 0.008 | S1 | 4.6 |
| Example 9 | P-G1 | 81.8 | I4 | 2.25 | I2 | 0.85 | R2 | 3.29 | M1 | 3.60 | M2 | 3.60 | G1 | 0.008 | S1 | 4.6 |
| Example 10 | P-G1 | 81.8 | I5 | 2.25 | I2 | 0.85 | R2 | 3.29 | M1 | 3.60 | M2 | 3.60 | G1 | 0.008 | S1 | 4.6 |
| Example 11 | P-G1 | 81.8 | I6 | 2.25 | I2 | 0.85 | R2 | 3.29 | M1 | 3.60 | M2 | 3.60 | G1 | 0.008 | S1 | 4.6 |
| Example 12 | P-G1 | 81.8 | I1 | 2.25 | I2 | 0.85 | R1 | 3.29 | M3 | 7.20 | — | — | G1 | 0.008 | S1 | 4.6 |
| Example 13 | P-G1 | 81.8 | I1 | 2.25 | I2 | 0.85 | R1 | 3.29 | M4 | 7.20 | — | — | G1 | 0.008 | S1 | 4.6 |
| Example 14 | P-G1 | 81.8 | I1 | 2.25 | I2 | 0.85 | R1 | 3.29 | M5 | 7.20 | — | — | G1 | 0.008 | S1 | 4.6 |
| Example 15 | P-G1 | 81.8 | I1 | 2.25 | I2 | 0.85 | R1 | 3.29 | M6 | 7.20 | — | — | G1 | 0.008 | S1 | 4.6 |

TABLE 3

| | Pigment | | Photopolymerization | | | | Resin | | Polymerizable | | | | | | | |
|---|---|---|---|---|---|---|---|---|---|---|---|---|---|---|---|---|
| | derivative | | initiator | | | | solution | | monomer | | | | Surfactant | | Solvent | |
| | | Con- | | Con- | | Con- | | Con- | | Con- | | Con- | | Con- | | Con- |
| | Type | tent | Type 1 | tent | Type 2 | tent | Type | tent | Type 1 | tent | Type 2 | tent | Type | tent | Type | tent |
| Example 16 | P-G1 | 81.8 | I1 | 2.25 | I2 | 0.85 | R1 | 3.29 | M7 | 7.20 | — | — | G1 | 0.008 | S1 | 4.6 |
| Example 17 | P-G1 | 81.8 | I1 | 2.25 | I2 | 0.85 | R2 | 3.29 | M1 | 3.60 | M2 | 3.60 | G1 | 0.008 | S1 | 4.6 |
| Example 18 | P-G1 | 81.8 | I1 | 2.25 | I2 | 0.85 | R1 | 1.65 | M1 | 3.60 | M2 | 3.60 | G1 | 0.008 | S1 | 4.6 |
| | | | | | | | R2 | 1.65 | | | | | | | | |
| Example 19 | P-G1 | 81.8 | I1 | 2.25 | I2 | 0.85 | R1 | 3.29 | M1 | 3.60 | M2 | 3.60 | G1 | 0.008 | S1 | 2.3 |
| | | | | | | | | | | | | | | | S2 | 2.3 |
| Example 20 | P-G7 | 81.8 | I1 | 2.25 | I2 | 0.85 | R1 | 3.29 | M1 | 3.60 | M2 | 3.60 | G1 | 0.008 | S1 | 4.6 |
| Example 21 | P-G8 | 81.8 | I1 | 2.25 | I2 | 0.85 | R1 | 3.29 | M1 | 3.60 | M2 | 3.60 | G1 | 0.008 | S1 | 4.6 |
| Example 22 | P-G9 | 81.8 | I1 | 2.25 | I2 | 0.85 | R1 | 3.29 | M1 | 3.60 | M2 | 3.60 | G1 | 0.008 | S1 | 4.6 |
| Example 23 | P-G10 | 81.8 | I7 | 2.25 | I2 | 0.85 | R3 | 3.29 | M6 | 7.20 | — | — | G1 | 0.008 | S1 | 4.6 |
| Example 24 | P-G6 | 81.8 | I7 | 2.25 | I2 | 0.85 | R3 | 3.29 | M6 | 7.20 | — | — | G1 | 0.008 | S1 | 4.6 |
| Comparative | P-Gr1 | 81.8 | I7 | 2.25 | I2 | 0.85 | R3 | 3.29 | M6 | 7.20 | — | — | G1 | 0.008 | S1 | 4.6 |
| Example 1 | | | | | | | | | | | | | | | | |
| Comparative | P-Gr2 | 81.8 | I7 | 2.25 | I2 | 0.85 | R3 | 3.29 | M6 | 7.20 | — | — | G1 | 0.008 | S1 | 4.6 |
| Example 2 | | | | | | | | | | | | | | | | |

In the above tables, details of the materials indicated by abbreviations are as follows.

### (Pigment Dispersion Liquid)

P-G1 to P-G10, P-Gr1, P-Gr2: pigment dispersion liquids P-G1 to P-G10, P-Gr1, and P-Gr2 described above

### (Photopolymerization Initiator)

I1: Omnirad 379 (manufactured by IGM Resins B.V.)
I2: Omnirad 2959 (manufactured by IGM Resins B.V.)
I3: IRGACURE OXE01 (manufactured by BASF)
I4: IRGACURE OXE02 (manufactured by BASF)
I5: IRGACURE OXE03 (manufactured by BASF)
I6: NCI-831 (manufactured by ADEKA Corporation)
I7: KAYACURE DETX-S (manufactured by Nippon Kayaku Co., Ltd.)

### (Resin Solution)

R1: 40 mass % PGMEA solution of a resin having the following structure (weight-average molecular weight: 11,000; a numerical value described together with the main chain indicates a molar ratio)

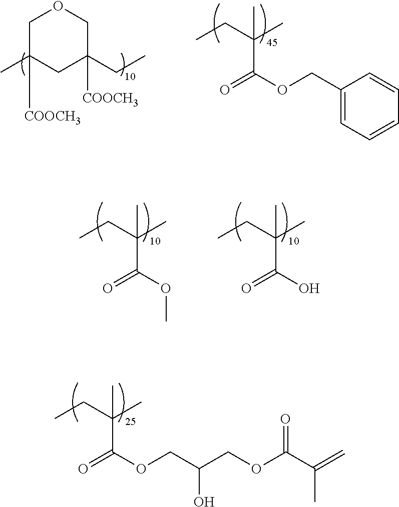

R2: 40 mass % cyclohexanone solution of a resin having the following structure (weight-average molecular weight: 12,000; a numerical value described together with the main chain indicates a molar ratio)

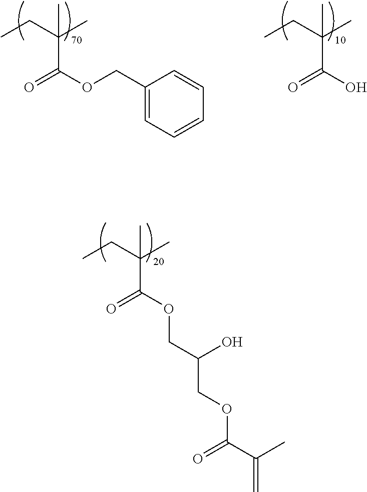

R3: 40 mass % PGMEA solution of a resin having the following structure (weight-average molecular weight: 15,000; a numerical value described together with the main chain indicates a molar ratio)

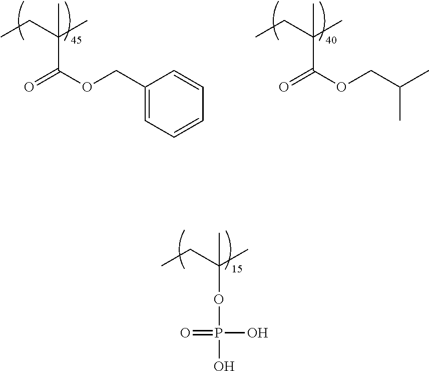

### (Polymerizable Monomer)

M1: compound having the following structure

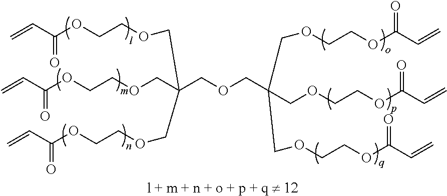

M2: compound having the following structure

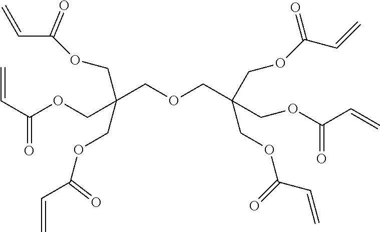 [SMILES: C=CC(=O)OCC(COCC(COC(=O)C=C)(COC(=O)C=C)COC(=O)C=C)(COC(=O)C=C)COC(=O)C=C]

M3: compound having the following structure (a+b+c=3)
M4: compound having the following structure (a+b+c=4)
M5: mixture of compounds having the following structure (compound of a+b+c=5: compound of a+b+c=6=3:1 (molar ratio))

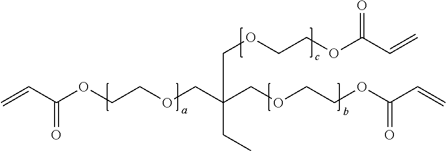

M6: compound having the following structure

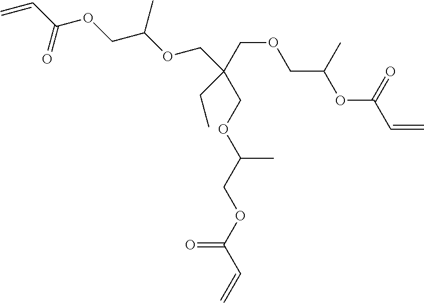 [SMILES: C=CC(=O)OCC(C)OCC(CC)(COCC(C)OC(=O)C=C)COC(C)COC(=O)C=C]

M7: compound having the following structure

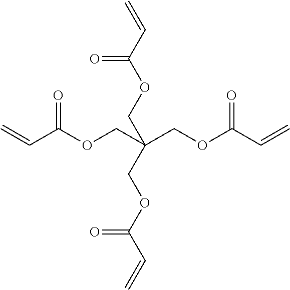 [SMILES: C=CC(=O)OCC(COC(=O)C=C)(COC(=O)C=C)COC(=O)C=C]

### (Surfactant)

G1: KF-6001 (manufactured by Shin-Etsu Chemical Co., Ltd., silicone-based surfactant)

### (Solvent)

S1: cyclohexanone

The content of each material in the colorant contained in each coloring composition is shown in the following tables. In the following tables, “PG7” represents C. I. Pigment Green 7, “PG36” represents C. I. Pigment Green 36, “PG58” represents C. I. Pigment Green 58, “PG59” represents C. I. Pigment Green 59, “PY185” represents C. I. Pigment Yellow 185, “PY139” represents C. I. Pigment Yellow 139, “PY150” represents C. I. Pigment Yellow 150, “PY129” represents C. I. Pigment Yellow 129, “PY138” represents C. I. Pigment Yellow 138, and “PY215” represents C. I. Pigment Yellow 215.

In addition, the numerical value in the column of “Proportion 1 of PG7” in the tables is part by mass of C. I. Pigment Green 7 with respect to 100 parts by mass of C. I. Pigment Yellow 185, the numerical value in the column of “Proportion 1 of PG36” in the tables is part by mass of C. I. Pigment Green 36 with respect to 100 parts by mass of C. I. Pigment Yellow 185, the numerical value in the column of “Proportion 1 of PY139” in the tables is part by mass of C. I. Pigment Yellow 139 with respect to 100 parts by mass of C. I. Pigment Yellow 185, the numerical value in the column of “Proportion 1 of PY150” in the tables is part by mass of C. I. Pigment Yellow 150 with respect to 100 parts by mass of C. I. Pigment Yellow 185, and the numerical value in the column of “Proportion 2 of PY150” in the tables is part by mass of C. I. Pigment Yellow 150 with respect to 100 parts by mass of C. I. Pigment Yellow 139.

TABLE 4

| | | Example 1 | Example 2 | Example 3 | Example 4 | Example 5 | Example 6 | Example 7 | Example 8 |
|---|---|---|---|---|---|---|---|---|---|
| Colorant | PG7 | 38.7% | 24.2% | 38.7% | 38.7% | 38.7% | 38.7% | 24.2% | 38.7% |
| | PY185 | 1.7% | 3.2% | 1.7% | 1.7% | 1.7% | 1.7% | 3.2% | 1.7% |
| | PY139 | 37.2% | 28.9% | 37.2% | 37.2% | 37.2% | 37.2% | 28.9% | 37.2% |
| | PG36 | 17.7% | 34.5% | — | — | — | — | 34.5% | 17.7% |
| | PG58 | — | — | 17.7% | — | — | — | — | — |
| | PG59 | — | — | — | 17.7% | 17.7% | 17.7% | — | — |
| | PY150 | 4.7% | 9.2% | 4.7% | 4.7% | — | — | 9.2% | 4.7% |
| | PY129 | — | — | — | — | 4.7% | — | — | — |
| | PY138 | — | — | — | — | — | — | — | — |
| | PY215 | — | — | — | — | — | 4.7% | — | — |

| | | | | | | | | |
|---|---|---|---|---|---|---|---|---|
| Proportion 1 of PG7 | 2332 | 769 | 2332 | 2332 | 2332 | 2332 | 769 | 2332 |
| Proportion 1 of PG36 | 1063 | 1094 | 0 | 0 | 0 | 0 | 1094 | 1063 |
| Proportion 1 of PY139 | 2237 | 917 | 2237 | 2237 | 2237 | 2237 | 917 | 2237 |
| Proportion 1 of PY150 | 284 | 292 | 284 | 284 | 0 | 0 | 292 | 284 |
| Proportion 2 of PY150 | 13 | 32 | 13 | 13 | 0 | 0 | 32 | 13 |

TABLE 5

| | | Example 9 | Example 10 | Example 11 | Example 12 | Example 13 | Example 14 | Example 15 | Example 16 |
|---|---|---|---|---|---|---|---|---|---|
| Colorant | PG7 | 38.7% | 38.7% | 38.7% | 38.7% | 38.7% | 38.7% | 38.7% | 38.7% |
| | PY185 | 1.7% | 1.7% | 1.7% | 1.7% | 1.7% | 1.7% | 1.7% | 1.7% |
| | PY139 | 37.2% | 37.2% | 37.2% | 37.2% | 37.2% | 37.2% | 37.2% | 37.2% |
| | PG36 | 17.7% | 17.7% | 17.7% | 17.7% | 17.7% | 17.7% | 17.7% | 17.7% |
| | PG58 | — | — | — | — | — | — | — | — |
| | PG59 | — | — | — | — | — | — | — | — |
| | PY150 | 4.7% | 4.7% | 4.7% | 4.7% | 4.7% | 4.7% | 4.7% | 4.7% |
| | PY129 | — | — | — | — | — | — | — | — |
| | PY138 | — | — | — | — | — | — | — | — |
| | PY215 | — | — | — | — | — | — | — | — |

| | | | | | | | | |
|---|---|---|---|---|---|---|---|---|
| Proportion 1 of PG7 | 2332 | 2332 | 2332 | 2332 | 2332 | 2332 | 2332 | 2332 |
| Proportion 1 of PG36 | 1063 | 1063 | 1063 | 1063 | 1063 | 1063 | 1063 | 1063 |
| Proportion 1 of PY139 | 2237 | 2237 | 2237 | 2237 | 2237 | 2237 | 2237 | 2237 |
| Proportion 1 of PY150 | 284 | 284 | 284 | 284 | 284 | 284 | 284 | 284 |
| Proportion 2 of PY150 | 13 | 13 | 13 | 13 | 13 | 13 | 13 | 13 |

TABLE 6

| | | Example 17 | Example 18 | Example 19 | Example 20 | Example 21 | Example 22 | Example 23 | Example 24 |
|---|---|---|---|---|---|---|---|---|---|
| Colorant | PG7 | 38.7% | 38.7% | 38.7% | 38.7% | 38.7% | 31.8% | 31.8% | 38.7% |
| | PY185 | 1.7% | 1.7% | 1.7% | 1.7% | 1.7% | 15.7% | 15.7% | 1.7% |
| | PY139 | 37.2% | 37.2% | 37.2% | 37.2% | 37.2% | 31.5% | 31.5% | 37.2% |
| | PG36 | 17.7% | 17.7% | 17.7% | 17.7% | 17.7% | 11.4% | 11.4% | — |
| | PG58 | — | — | — | — | — | — | — | — |
| | PG59 | — | — | — | — | — | — | — | 17.7% |
| | PY150 | 4.7% | 4.7% | 4.7% | 4.7% | 4.7% | 4.7% | 4.7% | — |
| | PY129 | — | — | — | — | — | — | — | — |
| | PY138 | — | — | — | — | — | — | — | — |
| | PY215 | — | — | — | — | — | — | — | 4.7% |

| | | | | | | | | |
|---|---|---|---|---|---|---|---|---|
| Proportion 1 of PG7 | 2332 | 2332 | 2332 | 2332 | 2332 | 202 | 202 | 2332 |
| Proportion 1 of PG36 | 1063 | 1063 | 1063 | 1063 | 1063 | 72 | 72 | 0 |
| Proportion 1 of PY139 | 2237 | 2237 | 2237 | 2237 | 2237 | 200 | 200 | 2237 |
| Proportion 1 of PY150 | 284 | 284 | 284 | 284 | 284 | 30 | 30 | 0 |
| Proportion 2 of PY150 | 13 | 13 | 13 | 13 | 13 | 15 | 15 | 0 |

TABLE 7

| | | Comparative | Comparative |
|---|---|---|---|
| | | Example 1 | Example 2 |
| Colorant | PG7 | 1.7% | 26.2% |
| | PY185 | 1.7% | 0.8% |
| | PY139 | 37.2% | 37.2% |
| | PG36 | — | — |
| | PG58 | 54.7% | 31.1% |
| | PG59 | — | — |
| | PY150 | — | — |
| | PY129 | — | — |
| | PY138 | 4.7% | 4.7% |
| | PY215 | — | — |

| | | |
|---|---|---|
| Proportion 1 of PG7 | 100 | 3333 |
| Proportion 1 of PG36 | 0 | 0 |
| Proportion 1 of PY139 | 2237 | 4722 |
| Proportion 1 of PY150 | 0 | 0 |
| Proportion 2 of PY150 | 0 | 0 |

### <Production of Film>

The coloring composition produced above was applied onto a glass substrate using a spin coater, such that a film thickness after drying was 2.0 μm, and dried on a hot plate at 100° C. for 2 minutes. Thereafter, using an ultra-high pressure mercury lamp, i-ray exposure was performed under conditions of an exposure illuminance of 20 mW/cm² and an exposure amount of 1 J/cm². Next, the coating film was heated on a hot plate at 100° C. for 20 minutes, and then cooled to produce a film.

### <Evaluation>

### (Evaluation of Moisture Resistance)

A high temperature and high humidity test was performed in which the film produced above was exposed to a temperature of 85° ° C. and a relative humidity of 85% for 1,000 hours. A transmittance of the film before and after the high temperature and high humidity test was measured in a wavelength range of 400 to 1,100 nm, an amount of change in transmittance was calculated for each measurement wavelength, the maximum value of the amount of change in transmittance was obtained, and the moisture resistance was evaluated according to the following standard.

The measurement of transmittance was performed 5 times for each sample, and the average value of the 3 times result except the maximum value and the minimum value was adopted. In addition, the maximum value of the amount of change in transmittance means a variation of transmittance of the film in a wavelength which has the largest variation of transmittance in a wavelength range of 400 to 1,100 nm before and after the high temperature and high humidity test.
5: maximum value of the amount of change in transmittance was 1% or less.
4: maximum value of the amount of change in transmittance was more than 1% and 2% or less.
3: maximum value of the amount of change in transmittance was more than 2% and 3% or less.
2: maximum value of the amount of change in transmittance was more than 3% and 4% or less.
1: maximum value of the amount of change in transmittance was more than 4%.

### (Evaluation of Light Resistance)

An ultraviolet cut filter (manufactured by AS ONE Corporation, KU-1000100) was mounted on the film produced above, and using a weather meter (manufactured by Suga Test Instruments Co., Ltd., Xenon Weather Meter SX75), a light resistance test was performed by irradiating the film with light of 100,000 1× over 50 hours under conditions of a temperature of 63° C. and a relative humidity of 50% in the apparatus. A transmittance of the film before and after the light resistance test was measured in a wavelength range of 400 to 700 nm, the maximum value of the amount of change in transmittance was obtained, and the light resistance was evaluated according to the following standard.

The measurement of transmittance was performed 5 times for each sample, and the average value of the 3 times result except the maximum value and the minimum value was adopted. In addition, the maximum value of the amount of change in transmittance means a variation of transmittance of the cured film in a wavelength which has the largest variation of transmittance in a wavelength range of 400 to 700 nm before and after the light resistance test.
5: maximum value of the amount of change in transmittance was 2% or less.
4: maximum value of the amount of change in transmittance was more than 2% and 3% or less.
3: maximum value of the amount of change in transmittance was more than 3% and 5% or less.
2: maximum value of the amount of change in transmittance was more than 5% and 10% or less.
1: maximum value of the amount of change in transmittance was more than 10%.

### (Evaluation of Development Residue)

The coloring composition produced above was applied onto a silicon wafer using a spin coater, such that a film thickness after drying was 2.0 μm, and dried at 100° C. for 2 minutes using a hot plate. Next, using an i-ray stepper exposure device FPA-3000 i5+ (manufactured by Canon Inc.), exposure was performed with light having an exposure amount of 200 mJ/cm² through a mask having a dot pattern of 3 μm square. Next, puddle development was performed at 23° C. for 60 seconds using a 0.3 mass % of tetramethylammonium hydroxide aqueous solution, rinsing was performed by a spin shower, and then washing with pure water was performed. Next, the silicon wafer was heated using a hot plate at 100° C. for 20 minutes to form a colored pattern (pixel). Among formed square dot patterns having a side length of 3 μm, a region where the cured colored pattern did not remain was observed with a length-measuring scanning electron microscope (SEM) (trade name: S-9260, manufactured by Hitachi High-Tech Corporation), and the development residue was evaluated according to the following standard.
5: no development residue was observed at all.
4: 1 to 5 pieces of development residues having a size (width of a portion having the longest axis) of 0.05 μm or less were observed.
3: 6 to 10 pieces of development residues having a size (width of a portion having the longest axis) of 0.05 μm or less were observed.
2: more than 10 pieces of development residues having a size (width of a portion having the longest axis) of 0.05 μm or less were observed, and no development residue having a size of more than 0.05 μm was observed.
1: more than 10 pieces of residues having a size (width of a portion having the longest axis) of 0.05 μm or less were observed, and a development residue having a size of more than 0.05 μm was also observed.

TABLE 8

| | Moisture | Light | Development |
|---|---|---|---|
| | resistance | resistance | residue |
| Example 1 | 5 | 5 | 5 |
| Example 2 | 5 | 5 | 5 |
| Example 3 | 5 | 4 | 5 |
| Example 4 | 5 | 4 | 5 |
| Example 5 | 4 | 5 | 5 |
| Example 6 | 4 | 4 | 5 |
| Example 7 | 3 | 3 | 5 |
| Example 8 | 5 | 5 | 5 |
| Example 9 | 5 | 5 | 5 |
| Example 10 | 5 | 5 | 5 |
| Example 11 | 5 | 5 | 5 |
| Example 12 | 5 | 5 | 5 |
| Example 13 | 5 | 5 | 5 |
| Example 14 | 5 | 5 | 5 |
| Example 15 | 5 | 5 | 5 |
| Example 16 | 5 | 5 | 3 |
| Example 17 | 5 | 5 | 4 |
| Example 18 | 5 | 5 | 5 |
| Example 19 | 5 | 5 | 5 |
| Example 20 | 5 | 5 | 5 |
| Example 21 | 5 | 5 | 5 |
| Example 22 | 4 | 3 | 4 |
| Example 23 | 4 | 3 | 4 |
| Example 24 | 3 | 3 | 3 |
| Comparative Example 1 | 2 | 1 | 1 |
| Comparative Example 2 | 2 | 1 | 1 |

As shown in the above table, in all of Examples, the evaluation of moisture resistance, the evaluation of light resistance, and the evaluation of development residue were excellent as compared with Comparative Examples.

In addition, in the coloring compositions of Examples 1 to 24, the maximal absorption wavelength of the film produced according to the above-described film forming method was in a wavelength range of 420 to 435 nm. In addition, the wavelength at which the transmittance was 50% was in a wavelength range of 515 to 525 nm and a wavelength range of 555 to 565 nm.

### <Manufacturing of Color Filter>

A coloring composition for forming a green pixel was applied onto a surface of a silicon wafer having a diameter of 8 inches (20.32 cm) by a spin coating method, such that a film thickness after film formation was 1.2 μm. Next, the coloring composition was heated using a hot plate at 90° C. for 120 seconds. Next, using an i-ray stepper exposure device FPA-3000 i5+(manufactured by Canon Inc.), the silicon wafer was exposed to light through a mask having a pattern at an exposure amount of 200 mJ/cm². Next, puddle development was performed at 23° C. for 60 seconds using a 0.3 mass % tetramethylammonium hydroxide aqueous solution. Next, the silicon wafer was rinsed by spin showering and was washed with pure water. Next, a green colored pattern (green pixel) was formed by heating at 100° C. for 900 seconds using a hot plate. In the same manner, a coloring composition for forming a red pixel and a coloring composition for forming a blue pixel were sequentially patterned to form a red colored pattern (red pixel) and a blue colored pattern (blue pixel), respectively, thereby producing a color filter.

As the coloring composition for forming a green pixel, the coloring compositions of Examples 1 to 24 were used.

As the coloring composition for forming a red pixel, a coloring composition for forming a red pixel 1 shown below was used.

As the coloring composition for forming a blue pixel, a coloring composition for forming a blue pixel 1 shown below was used.

The obtained color filter was incorporated into an organic electroluminescent display device according to a known method. This organic electroluminescent display device had a suitable image recognition ability.

### (Coloring Composition 1 for Forming Red Pixel)

The following components were mixed and stirred, and the obtained mixture was filtered through a nylon filter (manufactured by Nihon Pall Corporation) having a pore diameter of 0.45 μm to prepare the coloring composition 1 for forming a red pixel.

| | | |
|---|---|---|
| Red pigment dispersion liquid 1 | 60.31 | parts by mass |
| Photopolymerization initiator 1 | 0.83 | parts by mass |
| Photopolymerization initiator 2 | 0.58 | parts by mass |
| Resin solution 1 | 3.26 | parts by mass |
| Polymerizable monomer 1 | 0.83 | parts by mass |
| Polymerizable monomer 2 | 0.83 | parts by mass |
| Surfactant 1 | 0.004 | parts by mass |
| Propylene glycol monomethyl | 16.68 | parts by mass |
| ether acetate (PGMEA) | | |
| Cyclopentanone | 16.68 | parts by mass |

### (Coloring Composition 1 for Forming Blue Pixel)

The following components were mixed and stirred, and the obtained mixture was filtered through a nylon filter (manufactured by Nihon Pall Corporation) having a pore diameter of 0.45 μm to prepare the coloring composition 1 for forming a blue pixel.

| | | |
|---|---|---|
| Blue pigment dispersion liquid 1 | 56.7 | parts by mass |
| Violet dye solution 1 | 16.28 | parts by mass |
| Photopolymerization initiator 3 | 1.19 | parts by mass |
| Photopolymerization initiator 2 | 0.64 | parts by mass |
| Resin solution 1 | 0.93 | parts by mass |
| Polymerizable monomer 3 | 2.97 | parts by mass |
| Epoxy compound 1 | 1.40 | parts by mass |
| Surfactant 1 | 0.006 | parts by mass |
| Cyclohexanone | 19.89 | parts by mass |

Materials used for each coloring composition for forming a pixel are as follows.

Red pigment dispersion liquid 1: red pigment dispersion liquid 1 prepared by the following method

A mixed solution consisting of 10.0 parts by mass of C. I. Pigment Red 177, 3.50 parts by mass of C. I. Pigment Yellow 139, 1.50 parts by mass of the pigment derivative 1, 5.25 parts by mass of the dispersant 1, and 80.00 parts by mass of PGMEA was mixed and dispersed using a beads mill (zirconia beads having a diameter of 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. The dispersion treatment was repeated 10 times to obtain the red pigment dispersion liquid 1.

Pigment derivative 1: compound having the following structure

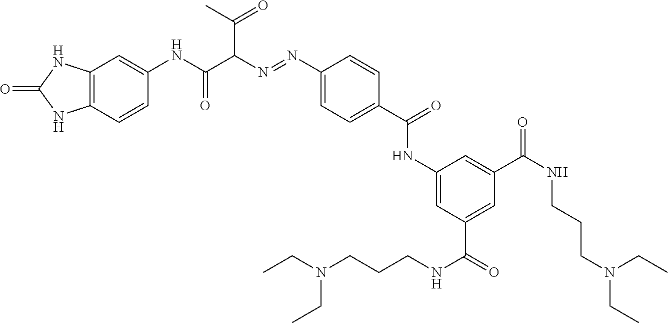 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Dispersant 1: resin having the following structure (a numerical value in parentheses of a main chain represents a molar ratio of each repeating unit, and a numerical value in parentheses of a side chain represents the repetition number of the repeating unit; weight-average molecular weight=20,000)

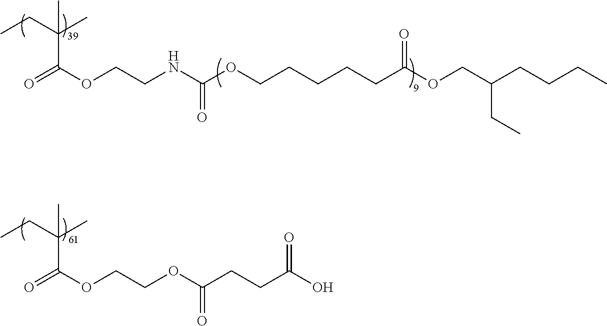

Blue pigment dispersion liquid 1: blue pigment dispersion liquid 1 prepared by the following method

A mixed solution consisting of 10.00 parts by mass of C. I. Pigment Blue 15:6, 3.50 parts by mass of a dispersant 2, and 86.50 parts by mass of PGMEA was mixed and dispersed for 3 hours using a beads mill (zirconia beads having a diameter of 0.3 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm² at a flow rate of 500 g/min. The dispersion treatment was repeated 10 times to obtain the blue pigment dispersion liquid 1.

Dispersant 2: resin having the following structure (a numerical value in parentheses of a main chain represents a molar ratio of each repeating unit; weight-average molecular weight=11,000)

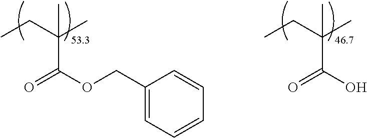

Violet dye solution 1: 20 mass % cyclohexanone solution of a dye having the following structure (in the structural formula shown below, iPr is an isopropyl group)

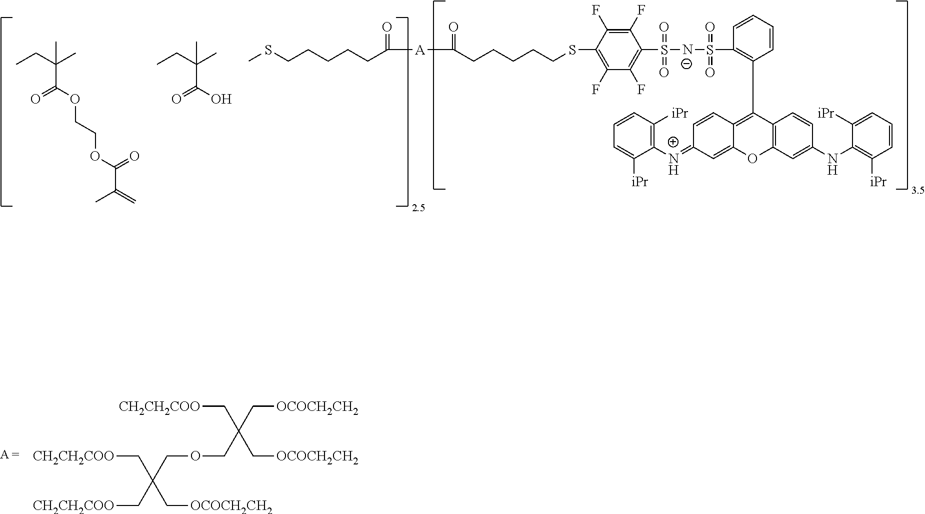

Photopolymerization initiator 1: Irgacure OXE03 (manufactured by BASF)
Photopolymerization initiator 2: Omnirad 2959 (manufactured by IGM Resins B.V.)
Photopolymerization initiator 3: compound having the following structure

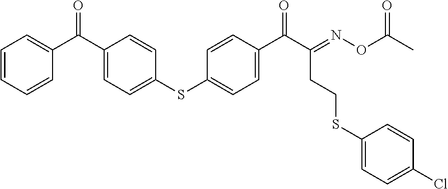 [SMILES: CC(=O)O/N=C(\CCSc1ccc(Cl)cc1)C(=O)c1ccc(Sc2ccc(C(=O)c3ccccc3)cc2)cc1]

Resin solution 1:40 mass % PGMEA solution of a resin having the following structure (weight-average molecular weight: 11,000; a numerical value described together with a main chain is a molar ratio)

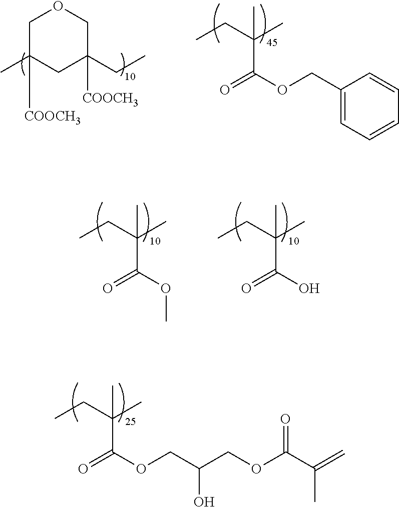

Polymerizable monomer 1: the above-described polymerizable monomer M1
Polymerizable monomer 2: the above-described polymerizable monomer M2
Polymerizable monomer 3: the above-described polymerizable monomer M3
Epoxy compound 1: EHPE3150 (manufactured by Daicel Corporation)
Surfactant 1: KF-6001 (manufactured by Shin-Etsu Chemical Co., Ltd., silicone-based surfactant)

What is claimed is:

1. A coloring composition comprising:
a colorant A;
a resin; and
a solvent,
wherein the colorant A contains
a Color Index Pigment Green 7,
a Color Index Pigment Yellow 185, and
a colorant a including three or more colorants selected from colorants other than the Color Index Pigment Green 7 and the Color Index Pigment Yellow 185, and
the coloring composition contains 200 to 3,000 parts by mass of the Color Index Pigment Green 7 with respect to 100 parts by mass of the Color Index Pigment Yellow 185.

2. The coloring composition according to claim 1,
wherein a content of the Color Index Pigment Yellow 185 in the colorant A is 0.5 to 30 mass %.

3. The coloring composition according to claim 1,
wherein the colorant a includes one or more green colorants other than the Color Index Pigment Green 7 and two or more yellow colorants other than the Color Index Pigment Yellow 185.

4. The coloring composition according to claim 3,
wherein the yellow colorant includes at least two selected from the group consisting of a Color Index Pigment Yellow 129, a Color Index Pigment Yellow 139, a Color Index Pigment Yellow 150, and a Color Index Pigment Yellow 215.

5. The coloring composition according to claim 3,
wherein the green colorant includes at least one selected from the group consisting of a Color Index Pigment Green 36, a Color Index Pigment Green 58, and a Color Index Pigment Green 59.

6. The coloring composition according to claim 1,
wherein the colorant a includes a Color Index Pigment Green 36, and
the coloring composition contains 50 to 1,500 parts by mass of the Color Index Pigment Green 36 with respect to 100 parts by mass of the Color Index Pigment Yellow 185.

7. The coloring composition according to claim 1,
wherein the colorant a includes a Color Index Pigment Yellow 139, and
the coloring composition contains 260 to 3,000 parts by mass of the Color Index Pigment Yellow 139 with respect to 100 parts by mass of the Color Index Pigment Yellow 185.

8. The coloring composition according to claim 1,
wherein the colorant a includes a Color Index Pigment Yellow 150, and
the coloring composition contains 10 to 400 parts by mass of the Color Index Pigment Yellow 150 with respect to 100 parts by mass of the Color Index Pigment Yellow 185.

9. The coloring composition according to claim 1,
wherein the colorant a includes a Color Index Pigment Yellow 139 and a Color Index Pigment Yellow 150, and
the coloring composition contains 5 to 100 parts by mass of the Color Index Pigment Yellow 150 with respect to 100 parts by mass of the Color Index Pigment Yellow 139.

10. The coloring composition according to claim 1,
wherein the colorant a includes a Color Index Pigment Yellow 139, a Color Index Pigment Yellow 150, and a Color Index Pigment Green 36.

11. The coloring composition according to claim 1,
wherein a content of the colorant A in a total solid content of the coloring composition is 25 to 60 mass %.

12. The coloring composition according to claim 1, further comprising:
a polymerizable monomer; and
a photopolymerization initiator.

13. The coloring composition according to claim 12,
wherein the polymerizable monomer includes a compound having an ethylenically unsaturated bond-containing group and an alkyleneoxy group.

14. The coloring composition according to claim 1, further comprising:
a surfactant,
wherein the surfactant includes a silicone-based surfactant.

15. A film formed of the coloring composition according to claim 1.

16. A color filter comprising:
the film according to claim 15.

17. A display device comprising:
the film according to claim 15.

18. A structure body comprising:
a green pixel formed of the coloring composition according to claim 1;
a red pixel; and
a blue pixel.

19. The structure body according to claim 18,
wherein the red pixel contains a colorant including a Color Index Pigment Red 177, and
a content of the Color Index Pigment Red 177 in the colorant contained in the red pixel is 30 mass % or more.
